(19) United States
(12) Patent Application Publication
(10) Pub. No.: US 2021/0215769 A1
(43) Pub. Date: Jul. 15, 2021

(54) STATE OF CHARGE (SOC) ESTIMATION USING CO-ESTIMATION

(71) Applicant: North Carolina State University, Raleigh, NC (US)

(72) Inventors: Mo-Yuen Chow, Raleigh, NC (US); Habiballah Rahimi Eichi, Raleigh, NC (US); Cong Sheng Huang, Raleigh, NC (US); Bharat Balagopal, Raleigh, NC (US)

(21) Appl. No.: 16/740,366

(22) Filed: Jan. 10, 2020

(51) Int. Cl. G01R 31/3835; G01R 31/367; H01M 10/0525; H01M 10/48; H01M 10/42

(52) U.S. Cl. CPC G01R 31/3835; G01R 31/367; H01M 10/0525; H01M 2220/20; H01M 10/425; H01M 2010/4271; H01M 10/48

(57) ABSTRACT

Battery parameters, state of charge, and state of health co-estimation are disclosed. According to an aspect, a method includes determining a terminal current and a terminal voltage of a battery. The method also includes maintaining a battery model that defines a relationship between a parameter of the battery, the terminal current, and the terminal voltage. Further, the method includes determining the parameter of the battery based on the battery model and the acquired terminal current and the terminal voltage. Temperature effects can also be accounted for by the co-estimation.

### CROSS REFERENCE TO RELATED APPLICATION

This application is a continuation-in-part of U.S. Non-Provisional patent application Ser. No. 14/285,853, filed May 23, 2014, which claims the benefit of and priority to U.S. Provisional Patent Application No. 61/827,586, filed May 25, 2013 and titled BATTERY PARAMETERS, STATE OF CHARGE (SOC), AND STATE OF HEALTH (SOH) CO-ESTIMATION, all of which are hereby incorporated herein by reference in their entireties.

### FEDERALLY SPONSORED RESEARCH OR DEVELOPMENT

This invention was made with government support under grant numbers 0812121 and 1500208 awarded by the National Science Foundation. The government has certain rights in the invention.

### TECHNICAL FIELD

The present subject matter relates to battery parameters, state of charge (SOC), and state of health (SOH) co-estimation.

### BACKGROUND

Advanced battery technology serves electric vehicles industry with employing different chemistries and assembling techniques to provide higher power and energy density. Nonetheless, the mere utilization of these technologies does not guarantee the efficiency, safety and reliability of the battery function. To ensure these features, the battery's status needs to be accurately monitored and controlled by the algorithms that are designed to perform battery management system (BMS). The total capacity is one of the most crucial characteristics of the battery that needs to be monitored. All of the methods that rely on the coulomb counting to estimate the State of Charge (SOC) need to have an accurate estimation of the total capacity. Moreover, the full capacity and its degradation due to aging is a prominent indicator to determine the State of Health (SOH) of the battery. Other than aging in the form of cycling or storage aging, the ambient temperature can also cause capacity fading that makes the total capacity of the battery different from the nominal capacity.

Future advanced transportation systems via Plug-In Hybrid Electric Vehicles (PHEV) and Plug-In Electric Vehicles (PEV) may not be feasible without significant improvements in battery technology and battery management systems. Moreover, a battery is a critical component in the infrastructure of the rapidly evolving smart grid. In addition to efficiency and reliability, which mostly depends on the battery technology, an accurate monitoring of the battery status information is essential for an effective power management of a smart grid. Battery status information includes SOC and SOH. Battery SOC may be defined as the percentage of the charge left in the battery divided by the battery rated capacity. Battery SOH is a factor to evaluate the ability of the battery to repeatedly provide its rated capacity over time. Several approaches have been proposed to estimate the SOC and SOH of a battery. These estimation approaches are mostly based on a dynamic model of the battery. Thus, a more precise battery modeling can result in a more accurate state estimation.

According to the accuracy and application, different types of battery models have been developed. Electrochemical models use complex partial differential equations to describe microscopic and macroscopic behaviors of the battery. Since these equations mostly need computational and time-consuming techniques to be solved, they are more appropriate for battery design optimization processes. Mathematical models are other tools to describe the dynamics of the battery using statistical and empirical data. These models are more appropriate to predict efficiency or capacity of the battery and are not able to give an explicit relationship between current, voltage, and temperature (measurable values of the battery) for simulation. Moreover, the mathematical models are not very accurate and usually come with 5-20% error.

For at least the aforementioned reasons, there is a need for improved systems and techniques for estimating battery parameters and functionality.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Battery parameters, state of charge, and state of health co-estimation are disclosed herein. According to an aspect, a method includes determining a terminal current and terminal voltage of a battery. The method also includes maintaining a battery model that defines a relationship between a parameter of the battery, the terminal current, and the terminal voltage. Further, the method includes determining the parameter of the battery based on the battery model and the acquired terminal current and terminal voltage.

### BRIEF DESCRIPTION OF THE DRAWINGS

The foregoing summary, as well as the following detailed description of various embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIG. 1 is a circuit diagram of a combined battery model with relaxation effect, internal resistance, and V_{OC}−SOC function, in accordance with various embodiments of the present disclosure;

FIG. 2 is a graph of an actual V_{OC}−SOC curve of the Li-polymer battery, in accordance with various embodiments of the present disclosure;

FIGS. 3A and 3B depict graphs of a first and second derivative, respectively, of V_{OC} versus SOC, in accordance with various embodiments of the present disclosure;

FIG. 4 is a graph of piecewise linear mapping of V_{OC}−SOC curve, in accordance with various embodiments of the present disclosure;

FIG. 5 is a circuit diagram of a battery-equivalent circuit, in accordance with various embodiments of the present disclosure;

FIG. 6 is a diagram of an observer structure, in accordance with various embodiments of the present disclosure;

FIG. 7 is a schematic diagram of an experimental set-up, in accordance with various embodiments of the present disclosure;

FIG. 8 depicts graphs of current and voltage of the battery, in accordance with various embodiments of the present disclosure;

FIGS. 9A-9D depict graphs of online identified battery parameters, in accordance with various embodiments of the present disclosure;

FIG. 10 is a diagram of b₀-b₁ relationship block diagram, in accordance with various embodiments of the present disclosure;

FIG. 11 is a graph of SOC estimation result from the updating observer, in accordance with various embodiments of the present disclosure;

FIG. 12 is a graph of SOC estimation error, in accordance with various embodiments of the present disclosure;

FIG. 13 is a block diagram that demonstrates the battery parameters/SOC co-estimation algorithm in accordance with embodiments of the present disclosure, in accordance with various embodiments of the present disclosure;

FIG. 14 is a block diagram that implements the battery capacity observer to estimate the battery capacity, in accordance with various embodiments of the present disclosure;

FIG. 15 shows graphs of current and voltage data obtained from the battery model, in accordance with various embodiments of the present disclosure;

FIGS. 16A-16D shows graphs of a comparison of the parameters identification results for nominal and updated capacity nominal and actual capacities, in accordance with various embodiments of the present disclosure;

FIG. 17 shows a graph of a comparison of SOC estimations with nominal and updated capacity, in accordance with various embodiments of the present disclosure;

FIG. 18 is a graph showing capacity estimation compared to the actual capacity of the battery, in accordance with various embodiments of the present disclosure;

FIGS. 19A-19D are graphs showing a comparison of the parameters identification results for the actual and the degraded capacity on the experimental data, in accordance with various embodiments of the present disclosure;

FIG. 20 is a graph showing a comparison of SOC estimations with nominal and degraded capacity for the experimental data, in accordance with various embodiments of the present disclosure; and

FIG. 21 is a graph showing estimated capacity compared to the nominal (actual) capacity for the experimental data, in accordance with various embodiments of the present disclosure;

FIG. 22 illustrates an example of a battery terminal voltage dynamic, in accordance with various embodiments of the present disclosure;

FIG. 23 illustrates an example of an electric circuit model (or battery-equivalent circuit) with two RC pairs, in accordance with various embodiments of the present disclosure;

FIG. 24 illustrates an example of a V_{OC}−SOC profile of a lithium-ion battery, in accordance with various embodiments of the present disclosure.

FIG. 25 illustrates an example of an identified state as a function of SOC and temperature (T), in accordance with various embodiments of the present disclosure.

FIG. 26 illustrates an example of an identified state with respect to SOC, in accordance with various embodiments of the present disclosure.

FIGS. 27A and 27B are images of an ADAC-HIL testbed and a 50 Ah lithium ion battery that was used for experimental testing, in accordance with various embodiments of the present disclosure.

FIGS. 28 and 29 illustrates examples of load current (I_{L}) and terminal voltage (V_{T}) of the pulse discharging profile (at 25° C.), in accordance with various embodiments of the present disclosure.

FIG. 30 illustrates an example of V_{OC}−SOC profiles at several temperature conditions, in accordance with various embodiments of the present disclosure.

FIG. 31 illustrates an example of the maximum available capacity of the batteries at various temperature conditions, in accordance with various embodiments of the present disclosure.

FIGS. 32 and 33 illustrate examples of Coulomb counting results at 25° C. and 0° C., in accordance with various embodiments of the present disclosure.

FIGS. 34A-34G illustrate examples of identified parameter profiles: (a) internal resistance (R₀), (b-c) resistances (R₁ and R₂), (d-e) capacitances (C₁ and C₂), and (f-g) RC pairs (R₁C₁ and R₂C₂) with respect to temperature, in accordance with various embodiments of the present disclosure.

FIGS. 35A-35G illustrate examples of identified parameter profiles: (a) internal resistance (R₀), (b-c) resistances (R₁ and R₂), (d-e) capacitances (C₁ and C₂), and (f-g) RC pairs (R₁C₁ and R₂C₂) with respect to the SOC of the battery at different temperature conditions, in accordance with various embodiments of the present disclosure.

FIGS. 36A-36D, 37A-37D and 38A-38D illustrate examples of SOC estimation results at 25° C. (cell #4), 45° C. (cell #4), and 0° C. (cell #1), in accordance with various embodiments of the present disclosure.

FIG. 39 is a schematic diagram illustrating an example of a computing (or processing) device that can be used for battery management, in accordance with various embodiments of the present disclosure.

### DETAILED DESCRIPTION

The presently disclosed subject matter is described with specificity to meet statutory requirements. However, the description itself is not intended to limit the scope of this patent. Rather, the inventors have contemplated that the claimed subject matter might also be embodied in other ways, to include different steps or elements similar to the ones described in this document, in conjunction with other present or future technologies.

Disclosed herein are electrical models and resistor-capacitor (RC) equivalent circuits for representing the dynamics of the battery more accurately. These models can be easy to implement and use low computational time and memory to be implemented. Optimal modeling for each battery and each particular application may be a trade-off between accuracy of the model and complexity and the order of the battery equations.

Despite the intrinsic nonlinear behavior of the battery, mainly caused by V_{OC}−SOC nonlinear function, a piecewise linear model for a battery is disclosed. Due to the strong background theory for linear systems and convenient design tools, design and analysis in the linear area is a significant benefit. On the other hand, considering the V_{OC}−SOC curve of the lithium polymer battery obtained from experimental tests makes the piecewise linear approximation of the V_{OC}−SOC function reasonable. This verification is discussed further herein. Therefore, considering a piecewise linear relationship between V_{OC} and SOC, the battery model can be presented as a linear system transfer function with step-wise varying parameters. This structure may be appropriate to apply an online parameter identification algorithm to estimate the parameters of the system that are changing with SOC. Identified herein are parameters of the linear system using a moving window least-squares (LS) identification method. Afterwards, the identified parameters can be used to update the parameters of the observer structure to estimate the SOC of the battery.

### Battery Modeling

In accordance with embodiments, equivalent circuits, systems, and methods are disclosed herein for modeling the dynamics of batteries. Based on the expected accuracy, different components can be added to the model to represent various characteristics of a battery. On the other side, embedding several components into the model can create a large amount of complexity and a system with a higher order. Therefore, considering the details in the model is a trade-off between accuracy and complexity. Described herein are some of the battery characteristics that can be used in the battery model for the present disclosure.

A. Linear Model with Internal Resistance

A typical battery can be modeled by a large capacitor. The capacitor can store a large amount of electrical energy in the charging mode and release it during discharging mode. Since charging/discharging is a chemical process with electrolyte and inter-phase resistance, a small resistor, R, can be used in series with a capacitor, C, for modeling. This small resistor can be referred to as the internal resistor of the battery and can change with the state of charge, the ambient temperature, and the aging effect of the battery.

### B. Relaxation Effect

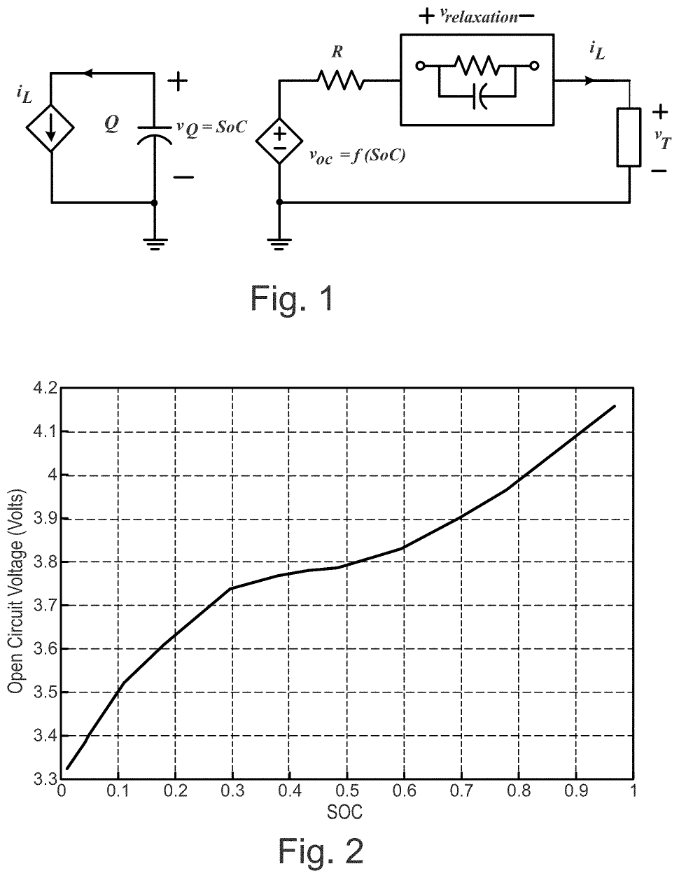

Relaxation effect is another fundamental battery characteristic that emerges in the cycles of charging and discharging. This effect represents the slow convergence of the battery open circuit voltage (V_{OC}) to its equilibrium point after hours of relaxation following charging/discharging. Relaxation effect is a phenomenon caused by diffusion effect and double layer charging/discharging effect. This characteristic is modeled by series-connected parallel RC circuits. Regarding the trade-off between accuracy and complexity, a different number of RC groups can be considered in the equivalent model. FIG. 1 shows the equivalent circuit for an example model that including the relaxation effect. More particularly, FIG. 1 shows a combined battery model with relaxation effect, internal resistance, and V_{OC}−SOC function. Moreover, another difference between this model and the linear model is that this model has a controlled voltage source to include the nonlinear relationship between open circuit voltage and the state of charge.

### C. V_{OC}−SOC Relationship

The V_{OC}−SOC relationship is a static characteristic of a battery under predetermined conditions of temperature and age. To model this nonlinear part of the battery, several nonlinear equation may be used. Some of the equations relating thereto also consider the hysteresis effect of the battery. The hysteresis effect can cause the discharging curve to stay below the charging curve for the same amount of SOC. Although the proposed models for the V_{OC}−SOC function are comprehensive, fitting the experimental V_{OC}−SOC curve to the equations results in modeling errors. Moreover, the nonlinearity of the model can increase the complexity of the analysis regarding stability and performance of the estimators. Therefore, considering the V_{OC}−SOC curve of the lithium polymer battery from experimental results, shown in FIG. 2 (which shows the actual V_{OC}−SOC curve of the Li-polymer battery), it provides the notion that it can be divided into several linear regions. The first and the second derivative of the V_{OC} versus SOC can be used to find out if a proper finite linear segments can be found for the V_{OC}−SOC curve. The first derivative

$$( \frac{\partial {V}_{OC}}{\partial SOC} )$$

and me second one

$$( \frac{{\partial }^{2} ( {V}_{OC} )}{{( \partial ( SOC ) )}^{2}} )$$

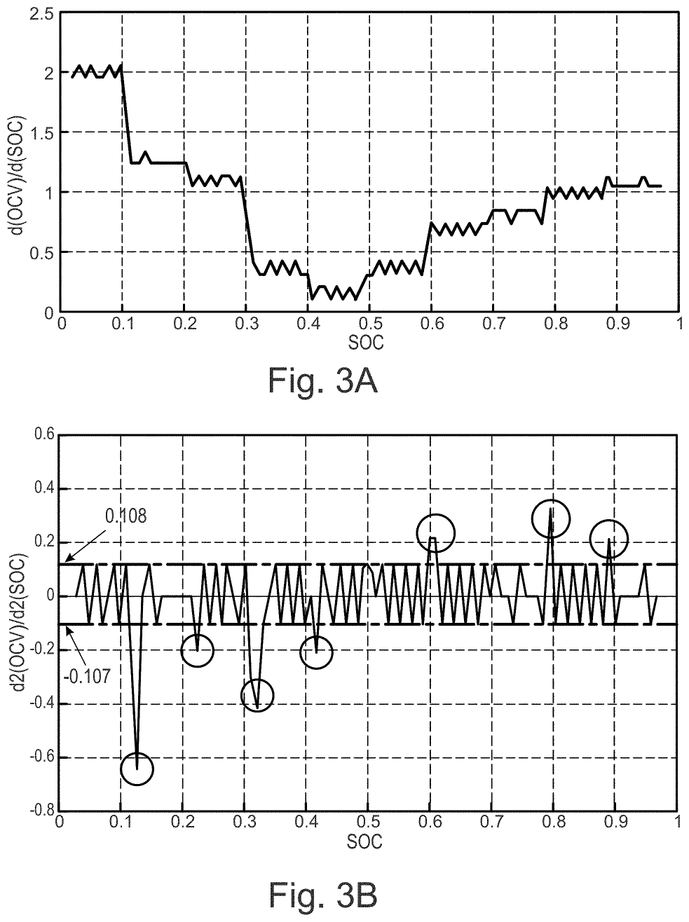

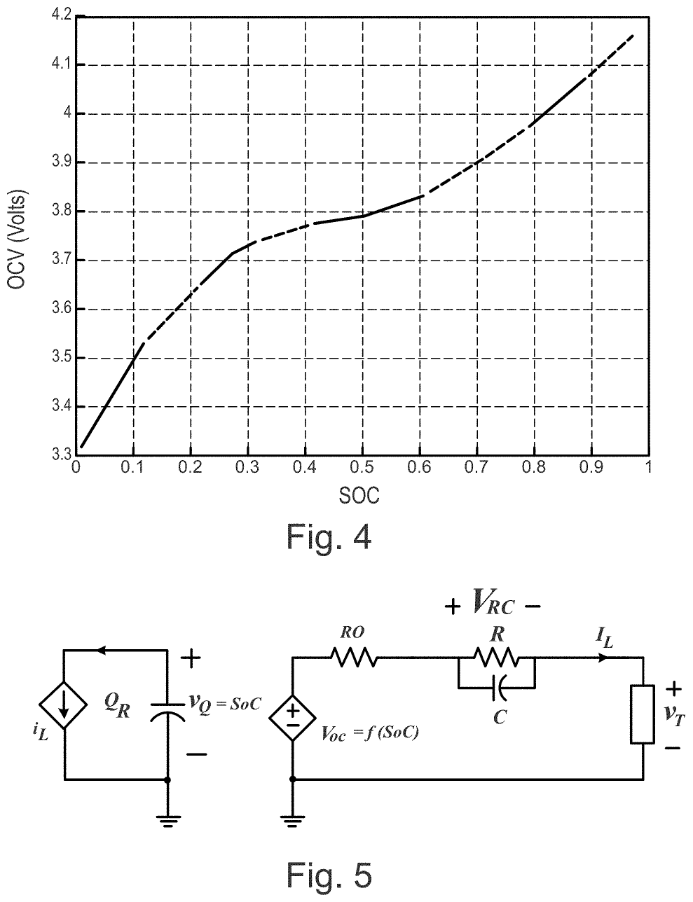

are displayed in FIGS. 3A and 3B, respectively. More particularly, FIGS. 3A and 3B show the first and the second derivative, respectively, of V_{OC} versus SOC. FIG. 3B shows that most of the second derivative values are within the small interval of [−0.107, 0.108] and a few (exactly 7) points stand out of this region. They can be considered as the cross points to divide the curve into linear segments. Therefore, as shown in FIG. 4, the V_{OC}−SOC curve is approximated by 8 segments, and each of them may be described by the following linear equation:

V_{OC}=f(SOC)=b₀+b₁SOC (1)

Using a least square error curve fitting technique, the values for b₀ and b₁ and the goodness of fit evaluation factor, R², can be derived for each segment. The results, presented in Table I below, shows that b₁ which is the slope of the mapping line starts from a large value of 1.97 for SOC<0.11, gradually decreases to the smallest value of 0.3 on the 5^{th} segment and afterwards increases to 1.05 for SOC>0.89. Moreover, the fitting criteria, R², indicates that segment 5 (0.4<SOC<0.6) has the worst fitting factor compared to the other segments. Segment 4 has the next worst fitting criteria; while the first and the last segments are the best fitted ones.

TABLE I
Parameters and fitness of piecewise linear segments

| | Param. | | |
|---|---|---|---|
| Seg. | b₀ | b₁ | R² |
| 1 | 3.3046 | 1.9702 | 0.9991 |
| 2 | 3.3861 | 1.2348 | 0.9997 |
| 3 | 3.4299 | 1.0337 | 0.9945 |
| 4 | 3.6407 | 0.3389 | 0.9933 |
| 5 | 3.6479 | 0.3014 | 0.9667 |
| 6 | 3.3746 | 0.7604 | 0.9979 |
| 7 | 3.1981 | 0.9892 | 0.9998 |
| 8 | 3.1442 | 1.0509 | 0.9999 |

### D. State-Space Equations for the Model

To model the battery characteristics, an equivalent circuit is used like that of FIG. 5 with one RC group to represent the relaxation effect. Although two RC groups may be used as the optimal trade-off between accuracy and complexity of the model, alternatively one RC group structure can provide sufficiently accurate results for a short time duration (e.g., seconds to minutes) prediction such as the applications in PHEV and PEV. Therefore, this model may be utilized to reduce the complexity of the model identification and the parameter extraction. Moreover, as we discussed earlier the V_{OC} vs. SOC function is mapped to several piecewise linear equations with the form of equation (1). Considering the equivalent circuit for the battery model in FIG. 5, the state-space equations can be written as system (2) to represent the battery dynamics. In these equations, the SOC of the battery, and the voltage across the RC cell, V_{RC}, are selected to be system state variables.

$$\{ \begin{matrix}[ \begin{matrix}\dot{SOC} \\ {\dot{V}}_{RC}\end{matrix} ] = [ \begin{matrix}0 & 0 \\ 0 & - \frac{1}{RC}\end{matrix} ] [ \begin{matrix}SOC \\ {V}_{RC}\end{matrix} ] + [ \begin{matrix}1 / {Q}_{R} \\ 1 / C\end{matrix} ] {I}_{L} \\ {V}_{T} = [ \begin{matrix}{b}_{1} & 1\end{matrix} ] [ \begin{matrix}SOC \\ {V}_{RC}\end{matrix} ] + {R}_{0} {I}_{L} + {b}_{0}\end{matrix} . \qquad ( 2 )$$

Herein, it is assumed that the terminal current (I_{L}) and voltage (V_{T}) are the only two values that are accessible from system (2). Herein, the temperature effect and the capacity fading are not considered to be caused by aging of the battery. To obtain the estimated SOC as one of the states, the parameters in system (2) need to be identified. Apparently, Q_{R} is known to be the nominal capacity of the battery. So, {b₀, R, C, R₀, b₁, SOC, V_{RC}} can be estimated as {\hat{b}₀, \hat{R}, Ĉ, \hat{R}, \hat{b}₁, [symbol] , \hat{V}_{RC}} using system parameter identification methods and state estimation.

### System Parameter Identification and State Estimation

### A. Least-Squares (LS) and Recursive Least-Squares Parameter (RLS) Identification

In order to identify the parameters of a linear time-invariant (LTI) system, the relationship between the system input/output (I/O) samples can be described by a standard structure, such as the autoregressive exogenous model (ARX model):

A(q)y(q)=B(q)u(q)+e(q), (3)

in which,

A(q)=1+a₁q⁻¹+ . . . +aₙq⁻ⁿ, (4)

B(q)=b₀+b₁q⁻¹+ . . . +bₘg^{-m} (5)

and e(q) is a zero mean Gaussian white noise. Therefore, with this model the output at the present step can be estimated by the input and output values at previous steps. Least Square (LS) identification approach provides a formula to minimize the least-square error between this estimated output value and the real output at present step. Since the input-output samples can be updated step-by-step while the system is running, the Recursive Least Square (RLS) is used to estimate the parameters of the system iteratively. Due to the fact that implementing the RLS algorithm is not easy in a real system and the I/O signal needs to be persistently exciting (PE) at each step, the moving-window LS method may be used, and this method is more practical. In this approach, the I/O data corresponding to a certain number of (window) past steps is used to estimate the parameters. The length of the window depends on the excitation of the input signal to properly reveal the dynamics of the system.

### B. Battery Parameter Identification

The parameters of the battery model needed to be estimated may include: {b₀, R, C, R₀, b₁}. Since most of the parameter identification methods use the transfer function of the system to identify the parameters, first the transfer function form of system (2) is obtained:

$$\frac{Y ( s ) - {b}_{0}}{U ( s )} = \frac{{R}_{0} {s}^{2} + ( \frac{{b}_{1}}{{Q}_{R}} + \frac{1}{C} + \frac{{R}_{0}}{RC} ) s + \frac{{b}_{1}}{{RCQ}_{R}}}{s ( s + \frac{1}{RC} )} , \qquad ( 5 )$$

From transfer function (16) and using bilinear transform

$$( s \to \frac{2}{T} \frac{z - 1}{z + 1} ) , \qquad$$

the discrete transfer function of system (2) with sample time T can be obtained:

$$\frac{Y ( {z}^{- 1} ) - {b}_{0}}{U ( {z}^{- 1} )} = \frac{{c}_{0} + {c}_{1} {z}^{- 1} + {c}_{2} {z}^{- 2}}{1 + {a}_{1} {z}^{- 1} + {a}_{2} {z}^{- 2}} , \qquad ( 6 )$$

where:

$$\begin{matrix}{c}_{0} = \frac{{T}^{2} {b}_{1} + 2 {Q}_{R} {R}_{0} T + 2 {Q}_{R} RT + 4 {Q}_{R} {R}_{0} RC + 2 {b}_{1} RCT}{2 {Q}_{R} T + 4 {Q}_{R} RC} , & ( 7 a ) \\ {c}_{1} = \frac{{T}^{2} {b}_{1} - 4 {Q}_{R} {R}_{0} RC}{{Q}_{R} T + 2 {Q}_{R} RC} , & ( 8 b ) \\ {c}_{2} = \frac{{T}^{2} {b}_{1} - 2 {Q}_{R} {R}_{0} T - 2 {Q}_{R} RT + 4 {Q}_{R} {R}_{0} RC - 2 {b}_{1} RCT}{2 {Q}_{R} T + 4 {Q}_{R} RC} , & ( 8 c ) \\ {a}_{1} = \frac{- 8 {Q}_{R} RC}{2 {Q}_{R} T + 4 {Q}_{R} RC} , & ( 8 d ) \\ {a}_{2} = \frac{- 2 {Q}_{R} T + 4 {Q}_{R} RC}{2 {Q}_{R} T + 4 {Q}_{R} RC} . & ( 8 e )\end{matrix}$$

According to equations (7) and (8), the time-domain relationship between different samples of input and output is as follows:

y(k)=a₁y(k−1)−a₂y(k−2)+b₀(1+a₁+a₂)+c₀u(k)+c₁u(k−1)+c₂u(k−2). (9)

Equations (8d) and (8e) imply that:

1+a₁+a₂=0, (10)

which means that the value of b₀ does not affect the estimation of the current output y(k), and subsequently, the other parameters. In other words, b₀ acts like an output offset that does not influence the dynamic between input and output. Therefore, solving equations (8a-e) can be shown to give a unique expression of the battery parameters versus the coefficients of the transfer function (7).

### C. Observer Design

After identifying the parameters of the battery, an observer may be designed to estimate the SOC, which is one of the states of the model. The observer can compare the real output to the estimated output of the model with the identified parameters. Then, it compensates for the error, caused by uncertainties and initial values, by giving a proper feedback to the states via a designed gain (observer gain).

Thus, in this stage the battery parameters {R, C, R₀, b₁, b₀} are assumed to be estimated as{\hat{R}, Ĉ, \hat{R}₀, \hat{b}₁, \hat{b}₀}. Moreover, the battery model is represented as a system with equations (11):

$$\{ \begin{matrix}\dot{x} = Ax + Bu \\ y = Cx + Du + {b}_{0}\end{matrix} \qquad ( 11 )$$

in which,

$${x}_{1} = {S}_{oc} , {x}_{2} = {V}_{RC} , A = [ \begin{matrix}0 & 0 \\ 0 & - \frac{1}{RC}\end{matrix} ] , B = [ \begin{matrix}1 / {Q}_{R} \\ 1 / C\end{matrix} ] , C = [ \begin{matrix}{b}_{1} & 1\end{matrix} ] , \\ D = {R}_{0} , u = {I}_{L} , y = {V}_{T} , x = [ \begin{matrix}{x}_{1} \\ {x}_{2}\end{matrix} ] .$$

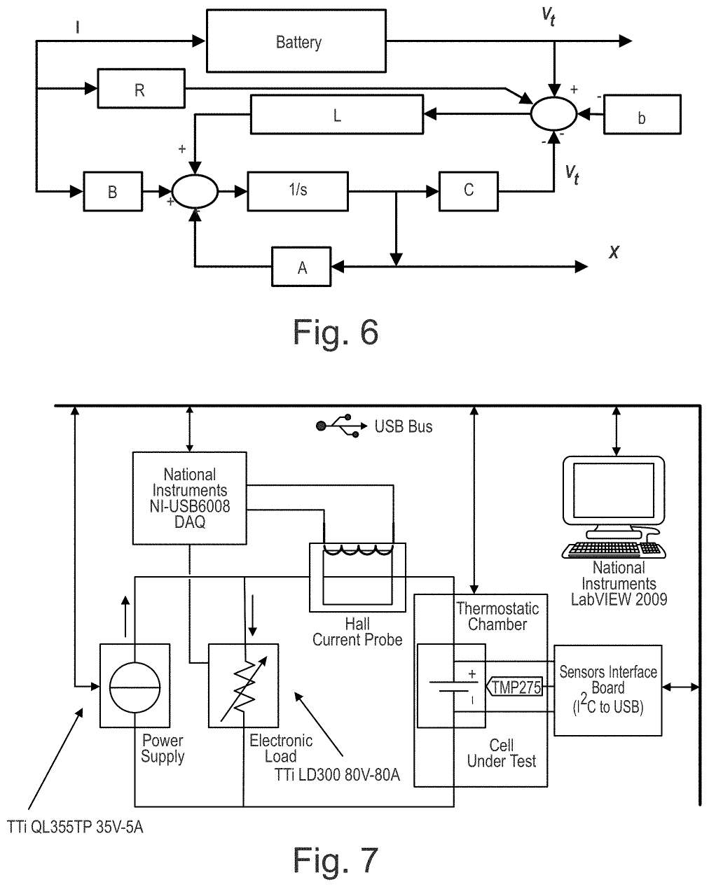

Therefore, the observer can be designed as a system with equations (12):

$$\{ \begin{matrix}{x}^{\dot{\hat{}}} = A \hat{x} + Bu + L ( y - \hat{y} ) \\ \hat{y} = C \hat{x} + Du + {b}_{0}\end{matrix} \qquad ( 12 )$$

in which L^{T}=[L₁ L₂] is the observer gain vector, and other arguments have the same dimensions as the corresponding arguments in system (11). From Equation (12), it can be seen that even though R, C, R₀ and b₁ are estimated accurately, there is no standard method of identifying b₀. A piecewise linear approximation for the V_{OC}−SOC curve may be utilized. Subsequently, a look-up table may be used to estimate b₀ based on the identified b₁. According to the experimental V_{OC}−SOC curve, piecewise linearization is not an accurate assumption for the battery. Therefore, another approach may be used in which a reduced-order observer is provided to estimate the SOC. With accurate identification of R, C, and R₀, the voltage across the RC group, V_{RC}, and the voltage drop on the internal resistance R₀I_{L}, can properly be estimated without using an observer. That is because the observer is basically used to compensate for the errors caused by initial values or uncertainties and in the case of V_{RC}, with negligible uncertainties. It can be shown that the dynamic of V_{RC} can compensate for the error caused by the initial value in a few pulses. Therefore, as shown in FIG. 6, the V_{OC} can be calculated by subtracting V_{RC} and R₀I_{L} from the terminal voltage V_{T}. Subsequently, using V_{OC} as the output of the reduced-order battery system, the observer equation is

$$SOC = \frac{1}{{Q}_{R}} {I}_{L} + L ( f ( SOC ) - {V}_{OC} )$$

in which f(SOC) is the experimental look-up table for V_{OC}−SOC relationship and L is the single-dimension observer gain. This observer structure with a proper gain can compensate the initial value and uncertainty error for SOC estimation.

FIG. 6 shows the block diagram of the observer. In this diagram, the estimated terminal voltage can be calculated by applying input, I_{L}, to a dynamic model with state space matrices of A, B, C and R₀ as D. Adding b₀ as an offset, this estimated out can be subtracted from the real terminal voltage of the battery to provide the error signal. This signal is magnified by the observer gain, L, to obtain the feedback to the estimated states of the battery.

### Battery Tests

Actual experiments have been carried out on lithium-polymer cells to validate the above described method. The lithium-polymer battery technology was selected because of its very high energy and power densities. These characteristics, along with other positive aspects, such as the very low self-discharge rate (around 3% per month) and the very high charge/discharge efficiency, common to other lithium-ion battery technologies, make this technology very attractive for improving the performance and the driving range of PHEVs and PEVs.

The tests were performed on 1.5 Ah lithium-polymer cells using the experimental set-up sketched in FIG. 7, which is a schematic diagram of the experimental set-up. The cell under test is placed inside a custom temperature-controlled chamber, so that the cell temperature can be kept at given value during a test. As shown in FIG. 7, a power supply and an electronic load to be charged and discharged at the desired current. The cell voltage and current are measured by a 16-bit ADC and an Agilent 1146 A 100 kHz/100 A AC/DC Hall current probe respectively. All the instruments are connected to a computer and managed by an application developed in LabVIEW graphical programming environment.

The cells (Kokam SLPB723870H4) used in the tests can continuously be charged and discharged within the 2.7V and 4.2V voltage range with currents up to 3 A and 30 A respectively. All the performed tests have the same structure, including an Init Phase, a Pause Phase and a Test Phase. During the Inn Phase the cell is completely charged (continuous-current followed by continuous-voltage mode) and then, after one hour pause, is completely discharged, with the current of 1.5 A. During the Pause (one hour) the cell settles down ensuring that all the transients subside before starting the real test (Test Phase), which will thus start from a well-known status. A significant example of the Test Phase is the pulsed charge/discharge cycle, which makes it possible to extract valuable characteristics of the cell under test. In particular, if the behavior of the cell terminal voltage during the zero current intervals is considered, and it is fitted with an exponential function, the open circuit voltage at the state of charge given by the coulomb counting of the measured cell current is given by the final value of the exponential fitting. This method was applied to derive the V_{OC}−SOC curve depicted in FIG. 2. For this purpose, each current pulse determined a 1% SOC variation and the following zero current interval lasted 5 minutes. In fact, two V_{OC}−SOC curves may be extracted, one during the charging phase and the other during the sequent discharging phase. A small difference can be observed between the two curves, confirming that the hysteresis effect is not so evident for lithium-polymer technology, as it is for the LiFePO₄ lithium-ion chemistry. The curve reported in FIG. 3 is the average between the charge and discharge V_{OC}−SOC curves.

### Results and Discussion

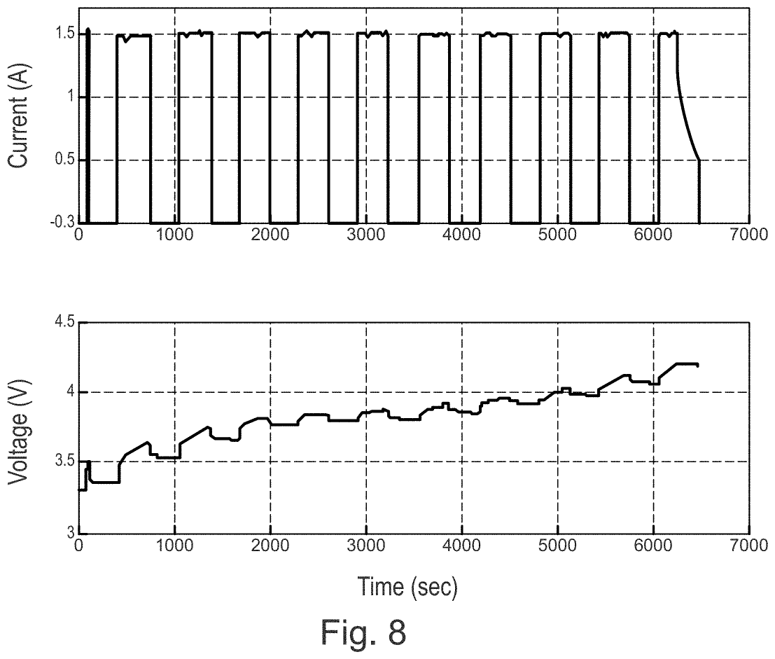

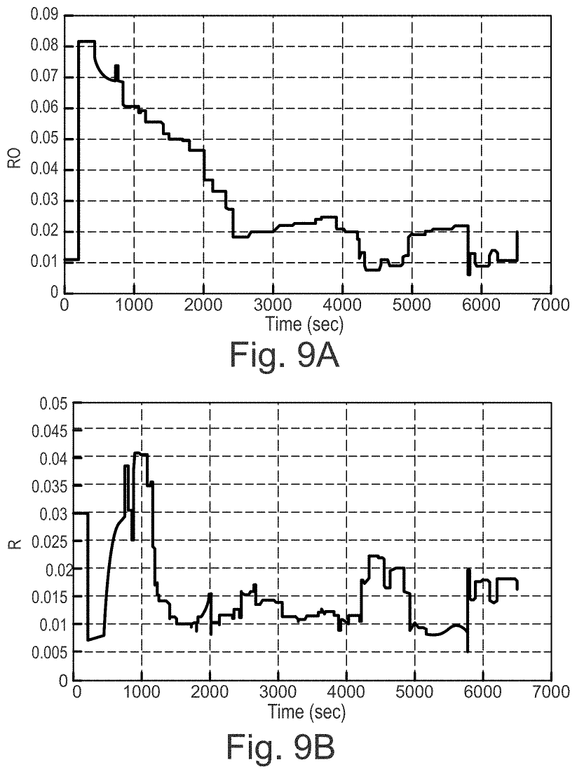

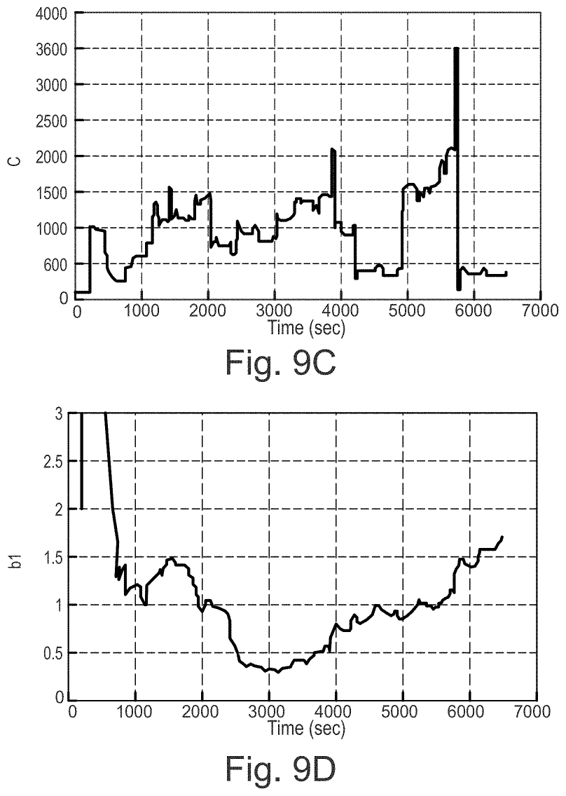

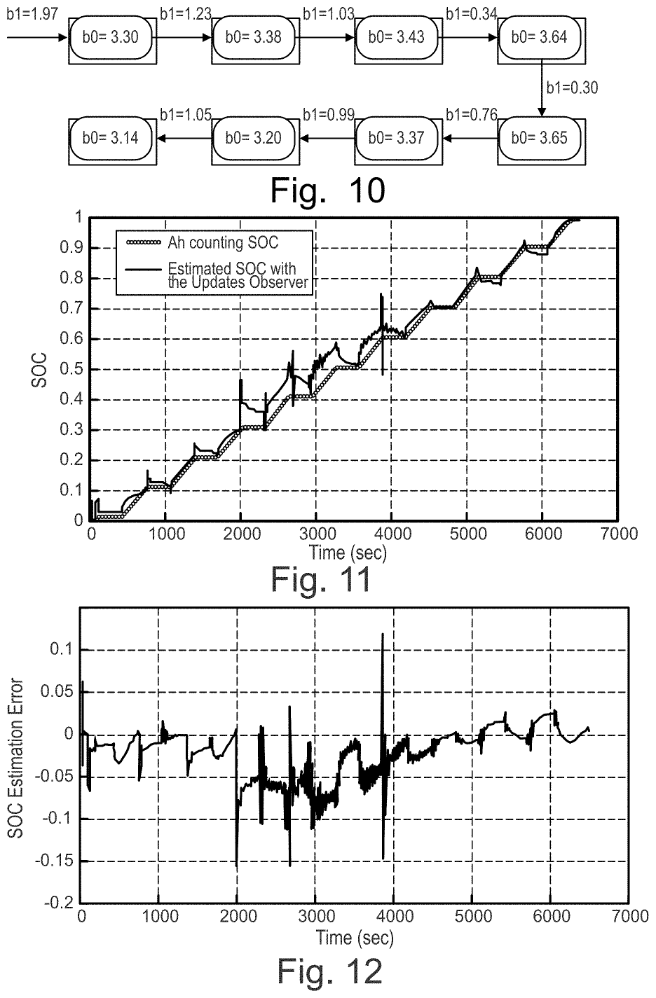

The data acquired during the experimental tests are used to evaluate the accuracy of the piecewise linear model for the battery, the online parameter identification algorithm, and the state estimation method. FIG. 8 shows the terminal current and voltage of the battery during a pulse charging of the Li-Polymer battery. These data are used as the input-output data to the moving window least square parameter identification algorithm. Since a step pulse is applied to the battery every 10 minutes (600 seconds), the moving window cannot be smaller than 300 seconds to at least include one of the pulse edges. The results for identification of the battery parameters are displayed in FIGS. 9A-9D. It can be observed that in this type of battery R₀, R and C change a lot with SOC. As expected, the value for the internal resistance, R₀, is large for small SOCs and decreases when SOC increases. This frequent change verifies the essential need for online parameter identification at least in this type of battery. Moreover, the values for b₁ in FIG. 9D follow the expected profile for b₁ in Table I for a charging cycle. The relationship between b₁ and b₀, obtained from Table I, is demonstrated in FIG. 10 as a sequential diagram. This block diagram finds the corresponding b₀, which is not identifiable with parameter estimation, for each value of b₁ considering the charging sequence. The identified parameters are used to update the observer parameters with the structure of FIG. 6. A pole placement technique is used to assign the observer poles at appropriate values and calculate the corresponding observer gains at each step. The result for the SOC estimation is demonstrated in FIG. 11. Since the initial SOC is known for this test, a coulomb counting method can be used to prepare a benchmark to evaluate the estimation of the observer that starts from an arbitrary initial SOC.

It can be observed from FIG. 11 that the estimated SOC with arbitrarily chosen initial SOC follows the real value for SOC. FIG. 12 shows the error in SOC estimation. It can be observed that most of the time the error is in the acceptable range of 5% except for the time corresponding to the SOC between 0.3 and 0.6. According to Table I, this range is related to segments 4 and 5 with relatively lower fitness criteria.

Despite the inherent nonlinear dynamic of the battery mainly caused by V_{OC}−SOC relationship, a piecewise linear model can be provided for the lithium-polymer battery. The experimental curve for V_{OC}−SOC function may be used to verify this assumption. The linear structure facilitates using the well-developed parameter identification and state estimation techniques in the linear systems to estimate the state of charge of the battery. Moreover, the linear structure of the estimator can be implemented in a battery management system. Applying the estimation approach to the experimental data of the lithium-polymer battery validates the acceptability of the SOC estimation results. On the other side, the piecewise linear model for the battery has the drawback of approximation error regarding the fact that V_{OC}−SOC function is not really linear. The increase in estimation error for the nonlinear segments implies the sensitivity of the approach to nonlinearity error.

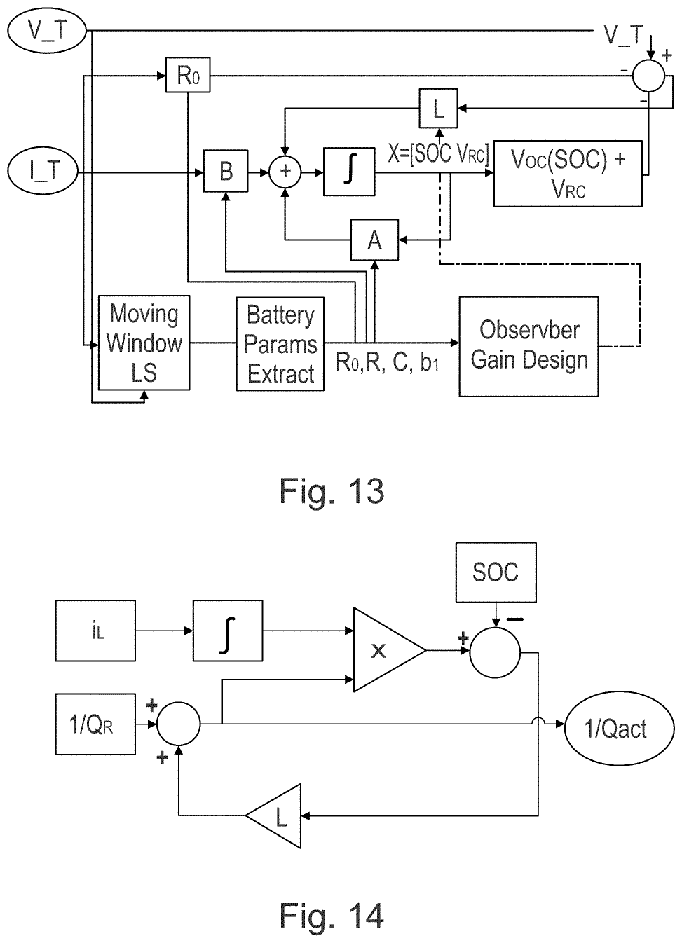

Referring again to FIG. 5, the battery dynamic may be modeled with an RC equivalent that includes one RC pair. A look-up table obtained from experimental data may be used to represent the V_{OC}−SOC relationship. Relying on the fact that the operating point's moving on the V_{OC}−SOC curve may be slow due to the large capacitor of the battery compared to the normal C-rates, a piecewise linear relationship between V_{OC} and SOC at the operating point may be considered. It may also be assumed that the terminal current (I_{L}) and voltage (V_{T}) are the only two values that are accessible from the system modeled by FIG. 13 and Equation (2). To obtain the estimated SOC as one of the states, the parameters in the system can be identified. As set forth herein, it may be presupposed that Q_{R} is the nominal capacity of the battery and accordingly estimate {b₀, R, C, R₀, b₁, SOC,V_{RC}} as {\hat{b}₀, \hat{R}, Ĉ, \hat{R}₀, \hat{b}₁, [symbol] ,\hat{V}_{RC}} using system parameter identification methods and state estimation. The aging effect that can be calendar and/or cycling effect may degrade the actual capacity of the battery. As demonstrated herein, keeping the nominal capacity, Q_{R}, instead of the actual capacity, Q_{act}, in the equations of the battery may not degrade the identification results of the other parameters.

### Mathematical Analysis

### Battery Parameter Identification

The transfer function form of the system modeled by FIG. 13 and Equation (2) may be represented as:

$$\frac{Y ( s ) - {b}_{0}}{U ( s )} = \frac{{R}_{0} {s}^{2} + ( \frac{{b}_{1}}{{Q}_{act}} + \frac{1}{C} + \frac{{R}_{0}}{RC} ) s + \frac{{b}_{1}}{{RCQ}_{act}}}{s ( s + \frac{1}{RC} )} = \frac{{b}_{00} {s}^{2} + {b}_{11} s + {b}_{22}}{{s}^{2} + {a}_{11} s + {a}_{22}} . \qquad ( 13 )$$

From transfer function (13) and using bilinear transform

$$( s \to \frac{2}{T} \frac{z - 1}{z + 1} ) , \qquad$$

the discrete transfer function of system (2) with sample time Tis obtained:

$$\frac{Y ( {z}^{- 1} ) - {b}_{0}}{U ( {z}^{- 1} )} = \frac{{c}_{0} + {c}_{1} {z}^{- 1} + {c}_{2} {z}^{- 2}}{1 + {a}_{1} {z}^{- 1} + {a}_{2} {z}^{- 2}} . \qquad ( 14 )$$

In order to identify the parameters of a linear system like Equation (13), the relationship between the system's input/output (I/O) samples is described by a standard structure, such as the autoregressive exogenous model (ARX) model:

A(q)y(q)=B(q)u(q)+e(q), (15)

where

A(q)=1+a₁q⁻¹+ . . . +aₙq⁻ⁿ, (16)

B(a)=b₀+b₁q⁻¹+ . . . +bₘq^{-m}, (17)

and e(q) is white noise (zero mean Gaussian noise). The LS identification approach provides a formula to minimize the Least Square (LS) error between this estimated output value and the real output at the present step. Since the I/O samples are being updated step-by-step while the system is running, a recursive least square (RLS) algorithm can be defined to identify the parameters of the system iteratively. Furthermore, because implementing the RLS algorithm is not easy in a real system and the I/O signal needs to be persistently exciting (PE) at each step, the moving-window LS (MWLS) method may be used, which is more practical. In this approach, the I/O data corresponding to a certain number (window) of past steps is used to estimate the parameters. Identifying the coefficients of the discrete transfer function (14), the reverse bilinear transform

$$( z \to \frac{2 + sT}{2 - sT} )$$

is used to find the coefficients of the continuous-time transfer function (13). Therefore, assuming that the coefficients {b₀₀, b₁₁, b₂₂, a₁₁, a₂₂} have been identified correctly using the I/O data, the battery parameters may be extracted from the transfer function (13) coefficients as shown in equations 18-22.

$$\begin{matrix}{R}_{0} = {b}_{00} & ( 18 ) \\ RC = \frac{1}{{a}_{11}} & ( 19 ) \\ {b}_{1} = {Q}_{act} RC {b}_{22} & ( 20 ) \\ \frac{1}{C} = {b}_{11} - \frac{{R}_{0}}{RC} - \frac{{b}_{1}}{{Q}_{act}} = {b}_{11} - \frac{{R}_{0}}{RC} - RC {b}_{22} & ( 21 ) \\ R = \frac{RC}{C} & ( 22 )\end{matrix}$$

While R₀ and RC are not dependent on Q_{act} in Equations (18) and (19), Equation (20) shows that b₁ cannot be determined without an accurate approximation of Q_{act}. Therefore, if there is a difference between Q_{act} and Q_{R}, the estimation of the b₁ may indicate the error. Nonetheless, when we use the non-accurate estimated b₁ to estimate C and R, as demonstrated in equations (19) and (20), respectively, the Q_{act} is cancelled out and the estimated results do not depend on the Q_{act}. To conclude, all the battery parameters except for b₁ can be identified uniquely without knowing the actual capacity of the battery. Since we use the V_{OC}−SOC look-up table instead of the identified value of b₁ in SOC estimation algorithm, the estimated b₁ does not affect the estimation results.

### SOC Estimation

After identifying the parameters of the battery, an observer may be used to estimate the SOC, which is one of the states of the model. Assuming that the battery's parameters {R, C, R₀, b₁, b₀} can be estimated as {\hat{R}, Ĉ, \hat{R}₀, \hat{b}₁, \hat{b}₀}, the battery model is represented as a system with Equation (23):

$$\{ \begin{matrix}\dot{x} = Ax + Bu \\ y = Cx + Du + {b}_{0}\end{matrix} , \qquad ( 23 )$$

where,

$${x}_{1} = {S}_{o c} , {x}_{2} = {V}_{R C} , A = [ \begin{matrix}0 & 0 \\ 0 & - \frac{1}{R C}\end{matrix} ] , B = [ \begin{matrix}1 / {Q}_{R} \\ 1 / C\end{matrix} ] , C = [ \begin{matrix}{b}_{1} & 1\end{matrix} ] , D = {R}_{0} , u = {I}_{L} , y = {V}_{T} , x = [ \begin{matrix}{x}_{1} \\ {x}_{2}\end{matrix} ] .$$

Therefore, the observer can be designed as a system with the Equation (24):

$$\{ \begin{matrix}\dot{\hat{x}} = A \hat{x} + Bu + L ( y - \hat{y} ) \\ \hat{y} = C \hat{x} + Du + {b}_{0}\end{matrix} , \qquad ( 24 )$$

where L^{T}=[L₁ L₂] is the observer gain vector. A linear quadratic (LQ) approach may be used to design an optimal observer that minimizes the error and effort. In this method, the P matrix may be calculated by solving the LQ Riccati equation (25),

AP+P^{T}A−PC^{T}R⁻¹CP=−Q, (25)

where Q and R are arbitrary semi-positive definite and positive definite matrices and the observer gain is obtained from Equation (26),

L^{T}=R⁻¹CP (26)

FIG. 13 illustrates a block diagram that demonstrates the battery parameters/SOC co-estimation algorithm in accordance with embodiments of the present disclosure. All the battery parameters and the observer gain may be updated in the structure. As shown in FIG. 13, the V_{OC}−SOC function may be used as a look-up table in the structure of the observer instead of using b₀ and b₁. Therefore, b₁ may be used only in designing the observer gain. However, the change in the C matrix caused by different b₁ only affects the optimality of the designed observer from the convergence time and control effort point of view. Moreover, investigating the structure of the observer shows that matrix B also contains the capacity of the battery. If the nominal capacity, Q_{R}, is used instead of the actual capacity, Q_{act}, to build this matrix, it can be shown that it does not influence the estimation of the SOC. That is because in this Luenberger type observer, the error between the actual state and the estimated state, e=\hat{x}−x, the observer error, converges to zero or the observer is asymptotically stable if the matrix A-LC has all negative eigenvalues. Therefore, the convergence of the observer may not depend on the B matrix. Simulation results endorse the fact that considering the nominal capacity instead of the actual capacity in the observer structure does not affect the SOC estimation results.

### Design the Battery Capacity Observer

After estimating the SOC with the parameters/SOC co-estimation method, another observer may be designed for a system that contains the coulomb counting equation to estimate the actual capacity of the battery. In this observer, the changes in the SOC of the battery may ultimately follow the coulomb counting equation in which the capacity is the actual one:

$$\dot{SOC} = \frac{1}{{Q}_{a c t}} I . \qquad ( 27 )$$

It is shown in the previous section that the estimation of SOC in the presently disclosed method is more based on the V_{OC} of the battery rather than coulomb counting. Therefore, the result of SOC estimation can be used as the measured value to estimate the actual capacity of the battery. The following system may be defined:

$$\{ \begin{matrix}Q ( k + 1 ) = Q ( k ) + w ( k ) \\ SOC ( k + 1 ) = S O C ( k ) + \frac{1}{Q ( k )} {I}_{L} \\ y ( k ) = S O C ( k )\end{matrix} , \qquad ( 28 )$$

where Q(k) is the actual capacity of the battery and w(k) is a Gaussian Noise. Since one of the states of the system (26), SOC, can be observed directly from the output data, a reduced order observer (equation (27)) may be designed to estimate the capacity of the battery.

$$\frac{1}{\hat{Q} ( k + 1 )} = \frac{1}{\hat{Q} ( k )} + L ( \hat{y} ( k ) - y ( k ) ) , \qquad ( 29 )$$

where \hat{Q}(k) is the estimated capacity of the battery and w(k) is the estimated output of system (28):

$$\{ \begin{matrix} ( k + 1 ) = ( k ) + \frac{1}{\hat{Q} ( k )} {I}_{L} \\ \hat{y} ( k ) = ( k )\end{matrix} \qquad ( 30 )$$

Since system (30) is nonlinear, instead of linear analytic design methods a trial and error approach may be used to design the observer gain, L. FIG. 14 illustrates a block diagram that implements the battery capacity observer described by equation (29) to estimate the battery capacity. As previously explained, y(t) is the output for system (28) which is SOC of the battery.

### Additional Simulation Results

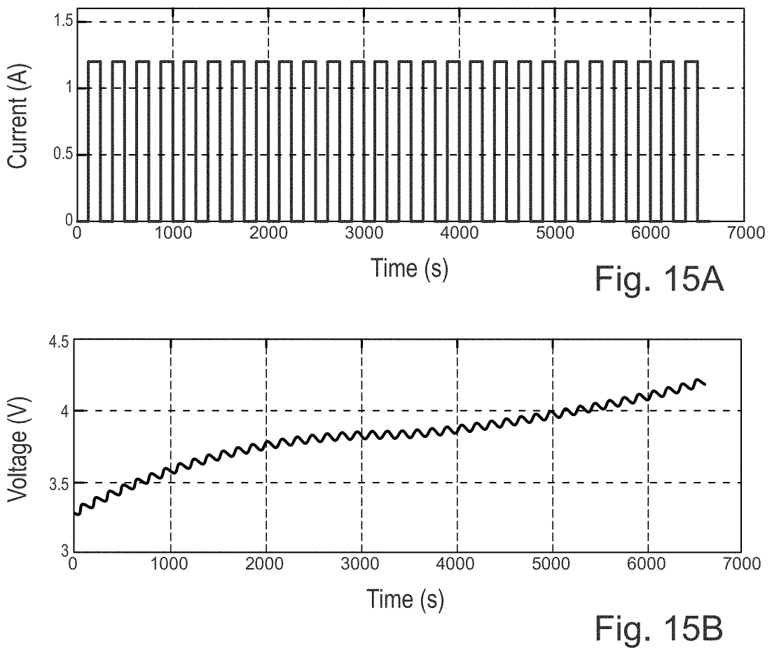

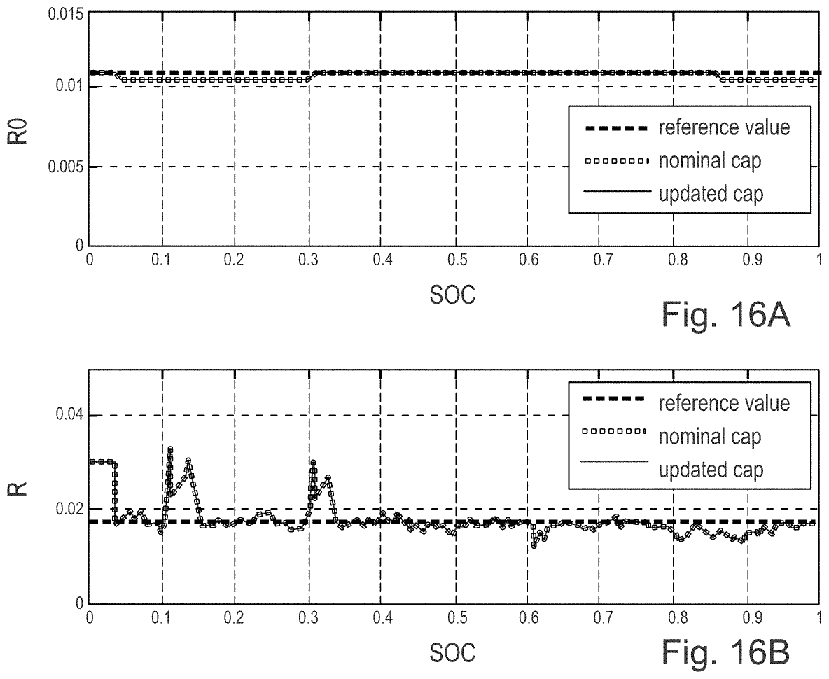

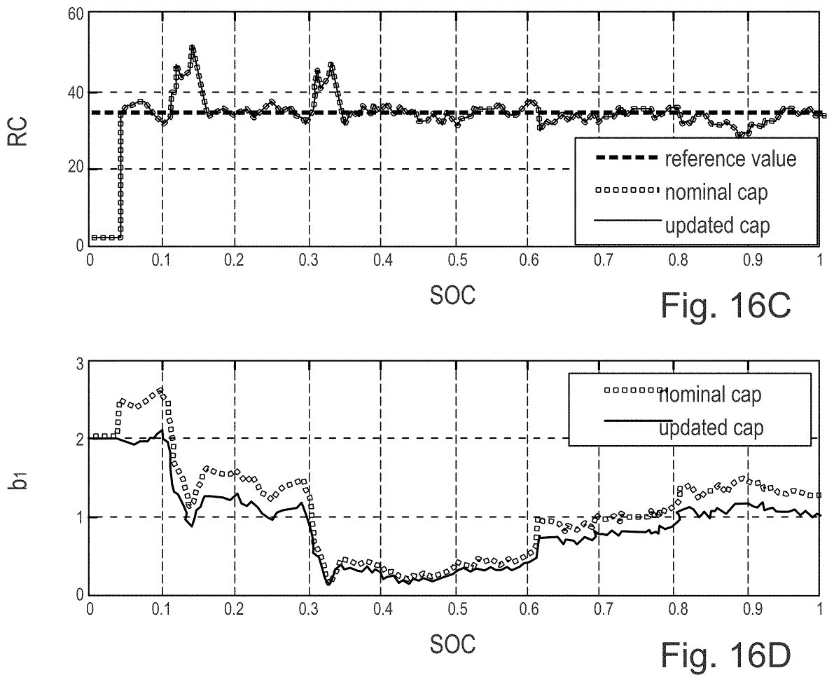

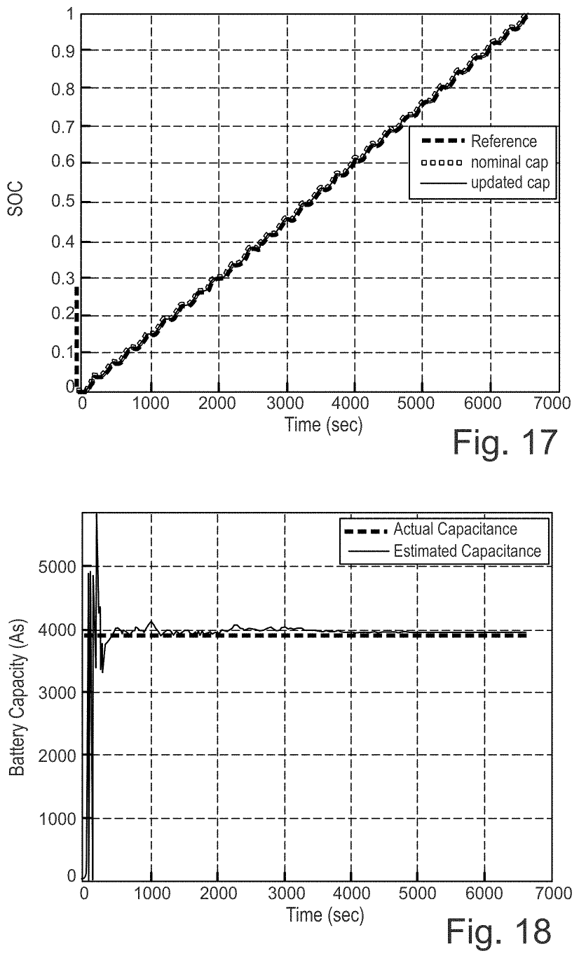

To demonstrate the robustness of the identification and SOC estimation results regarding the uncertainties in the full capacity calculation of the battery, the results may be evaluated using the input/output data from a nonlinear model of the battery. In this model which has been developed in SIMULINK, a look-up table obtained from the experimental data to represent the V_{OC}−SOC function may be used. Also, the battery dynamics are represented by an RC equivalent circuit shown in FIG. 5 with fixed values for R₀, R and C. Although those values change with SOC and C-rate in the real system, they may be kept fixed in this model to make the verification easier. The current and voltage data of the model may be obtained when the capacity of the battery is dropped by 20% of the nominal capacity, which is the extreme capacity degradation for most of the applications. It is similar to getting the current and voltage of a battery that has lost 20% of its capacity due to the cycling ageing effect. However, in the identification algorithm, the nominal capacity is considered as the natural approximation of the full capacity of the battery. Applying the input/output data, demonstrated in FIG. 14, to the parameters identification algorithm, the identified parameters are compared to the results from an algorithm with the actual full capacity. The identification results for both nominal and actual capacities are demonstrated in FIG. 17 with a thicker line for nominal capacity to illuminate the difference. FIG. 15 shows graphs of current and voltage data obtained from the battery model. FIGS. 16A-16D shows graphs of a comparison of the parameters identification results for nominal and updated capacity nominal and actual capacities. Also, the dotted lines show the reference value for the parameters that have been used in the simulated model. The first three graphs show that R₀, R and RC are identified at the same values for both nominal and actual capacities. These parameters are the major updating factors in the SOC co-estimation structure shown in FIG. 13. On the other side, as expected from Equation 18, FIGS. 16A-16D show that identification of b₁ is significantly affected by the assumption about the battery full capacity. However, following the earlier discussion, it does not influence the SOC estimation results because the experimental look-up table is used in the observer structure instead of b₁. FIG. 17 is a graph showing a comparison of SOC estimations with nominal and updated capacity. The simulation results demonstrated in FIG. 2 confirms that considering the nominal capacity instead of the degraded one does not make any significant difference in the estimation of the SOC. On the contrary, in FIG. 17 the difference between the estimated SOCs with different full capacity considerations slightly increases for the SOCs between 30% and 60%. This is the area in FIGS. 16A-16D that the difference between the identified bis is minimum compared to other SOCs. Therefore, we can see again that lack of observability has more negative influence on SOC estimation compared to the full capacity error influence. Afterwards, as shown in FIG. 15, when the estimated SOC is applied to the observer in FIG. 14 along with the battery current the parameters/SOC/capacity algorithm is able to accurately estimate the actual capacity of the battery. FIG. 18 is a graph showing capacity estimation compared to the actual capacity of the battery.

### Experimental Results

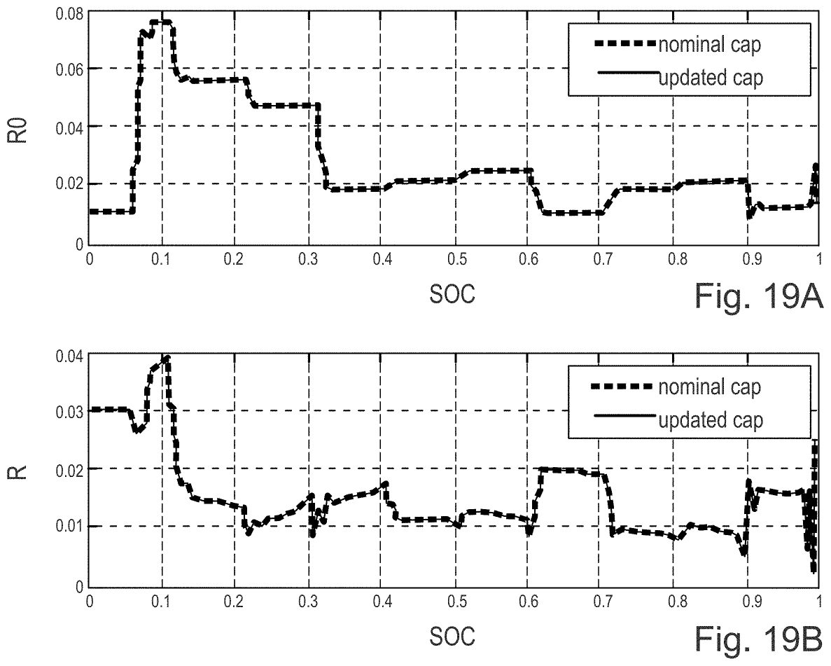

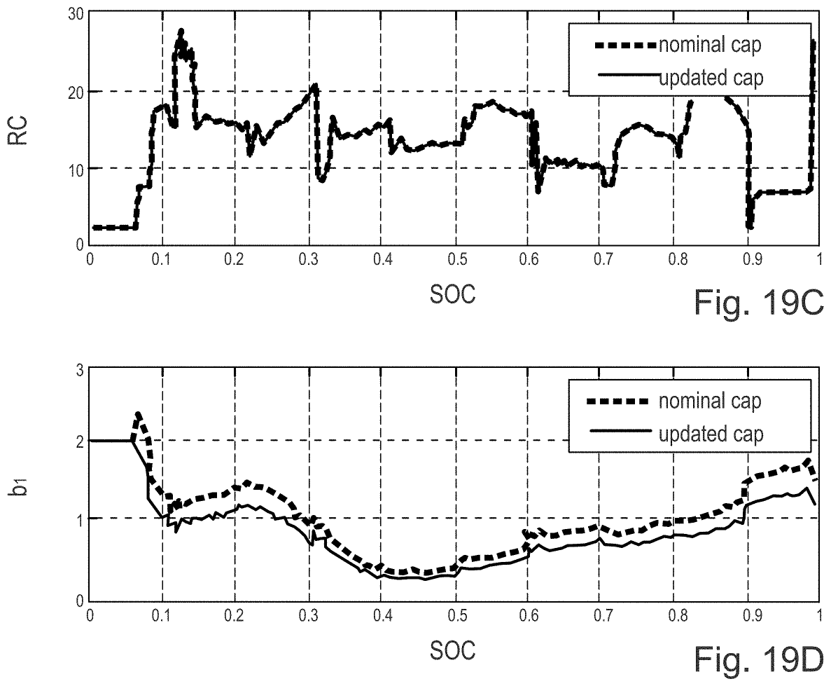

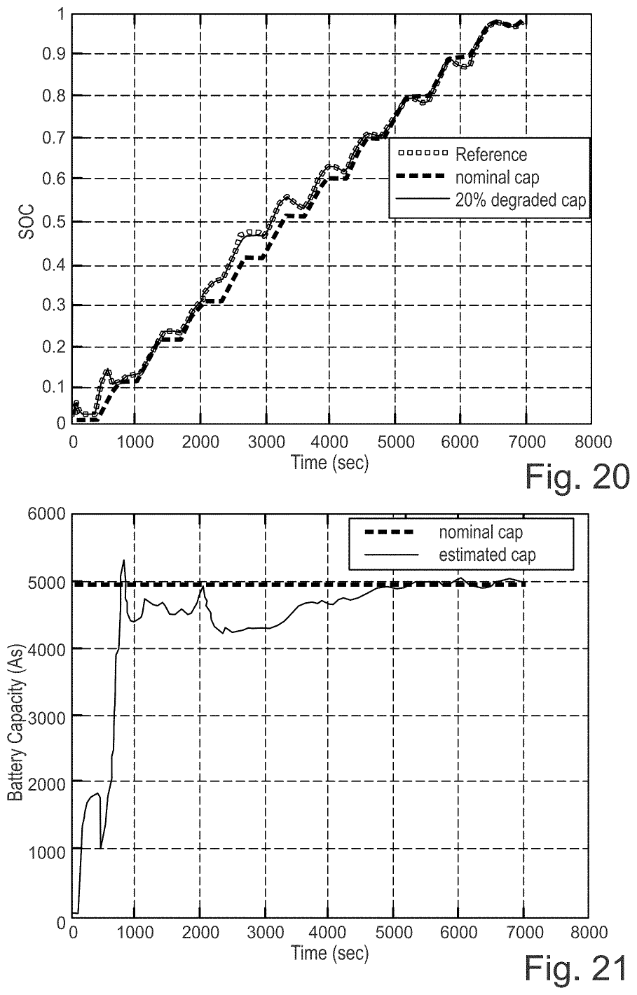

After verifying the performance of the parameters/SOC/capacity co-estimation algorithm using the simulated data, the current and voltage data obtained from the experimental tests on was applied on 1.36 Ah lithium-polymer cells (Kokam SLPB723870H4) to estimate the actual capacity of the cells. In this test, it was assumed that the capacity of the brand new battery is equal to the nominal capacity. Therefore, to evaluate the robustness of the algorithm, this time it was assumed that the full capacity of the battery in the parameters/SOC co-estimation algorithm is considered 20% lower than the nominal capacity. The results of the parameters/SOC co-estimation algorithm were compared for both nominal and 20% degraded capacity in the algorithm structure. The identified parameters in FIGS. 19A-19D shows that even in the experimental case in which the parameters vary with SOC, the wrong assumption about the full capacity of the battery does not deviate the identification of the main parameters, i.e., R₀, R and C. This figure also shows that b₁ is the only parameter that is identified differently for different assumption about the full capacity. But it does not affect the SOC estimation since look-up table is substituted in the algorithm structure. The SOC estimation results demonstrated in FIG. 20 confirms that considering a wrong value for the capacity does not influence the SOC estimation. Accordingly, the estimated SOC results were used to calculate the actual capacity of the lithium-Polymer battery cell using the online algorithm in FIG. 11. FIG. 21 presents the capacity estimation results compared to the nominal capacity of the battery. This figure shows that although the initial value for the estimated capacity is zero the algorithm is able to compensate the initial state error and estimate the full capacity almost accurately before t=2000s. The increase in the capacity estimation error between 2000s and 4000s is due to the error in SOC estimation that roots in the observability issue.

### Consideration of Temperature Effect for Co-Estimation

The world is in the midst of an energy revolution because of the gradual shift of energy dependency from fossil fuels to renewables. However, the power availability from the renewables is uncertain and intermittent. For example, PV (photovoltaic) panel generation is limited from sunrise to sunset and wind generators are restricted to locations with strong winds. Energy storage, therefore, is an essential component of renewables, to provide an energy reservoir. Among all types of batteries, lithium-ion batteries are strong candidates for energy storage in electric-vehicle and electric-grid applications due to their high energy density, long lifespan, negligible memory effect, and low self-discharging effect. After years of research, the technology of lithium-ion batteries has improved significantly in terms of the capacity, the power density, and the tolerance to extreme operating conditions, thereby increasing their adoption in numerous applications.

Even though lithium-ion batteries are widely accepted, accurate estimation of the State-of-Charge (SOC) of the battery in real-world applications is still under investigation. The SOC indicates the remaining energy left in the battery. It is one of the most important states of the battery, but it cannot be measured directly from the battery. The SOC can only be estimated from limited measurable battery signals, which include the load current and the terminal voltage of the battery. However, their relationship and the available capacity of the battery can also be functions of the temperature of the battery. The temperature of the battery is not only influenced by the ambient temperature, but also the utilization pattern. The temperature, therefore, can contribute to inaccurate SOC estimation.

To estimate the SOC of the battery from a limited number of signals, SOC estimation approaches can utilize Coulomb counting and voltage-based SOC estimation algorithms. The Coulomb counting approach can be used in wearable devices and mobile devices because of its simplicity and ease of implementation. This approach follows the definition of SOC in that it estimates the SOC of the battery by periodically counting the charge flow through the battery over a time period. However, the accuracy of Coulomb counting can be affected by (1) the initial SOC value, (2) the accumulated load current measurement error and (3) the available capacity of the battery. The first two variables can be calibrated by putting the battery in a known state, for example, fully charged or fully discharged. At these known states, the initial SOC can be considered to be 100% or 0%, respectively, and the accumulated measurement error of the load current can be reset to zero. The available capacity can be updated when the battery is discharged from full to empty and vice versa.

Even though the periodic updates help the SOC estimation accuracy, the performance of the Coulomb counting approach is still not assured in real-world applications. Batteries usually experience variations of temperature several times within a cycle. For example, a battery charges from the PV panels when the sun rises. The battery heats from the sun's radiation and self-heats during operation. The battery cools down when the sun sets or when the battery is at rest. The temperature variations within a cycle result in incorrect pre-defined available battery capacity. Without real-time capacity updates, the Coulomb counting method may not estimate the SOC of the battery accurately which may result in improper operations, such as over-charging and over-discharging. To avoid these improper operations, the operating range if the battery can be from about 20% to about 95% SOC.

Another SOC estimation approach can utilize voltage-based SOC estimation algorithms. This group of algorithms can estimate the SOC without input about the available capacity. This can avoid the temperature effect to some extent. These algorithms estimate the SOC of the battery based on the open-circuit voltage (V_{OC}) of the battery and a pre-determined V_{OC}−SOC profile of the battery. The open-circuit voltage is the terminal voltage when the battery is at rest and reaches electrochemical equilibrium. However, it is time consuming to acquire the open-circuit voltage, and may require at least a four-hour relaxation period for accurate measurement. The long relaxation period can be a challenge that makes these algorithms hard to implement in real-time applications. To shorten the relaxation time for the open-circuit voltage estimation, the battery can be considered a voltage source (open-circuit voltage) in series with an internal resistance. The open-circuit voltage then can be estimated by summing the terminal voltage with the voltage across the internal resistance. However, the internal resistance is not a constant during operation, and can also be influenced by the temperature of the battery.

Both algorithms, Coulomb counting and the voltage-based approach, may not provide accurate SOC estimation in real-world applications due to their inability to adapt to the temperature condition. To adapt to the battery dynamics, which include the available capacity of the battery, the terminal voltage dynamics, and the V_{OC}−SOC profile, three battery models were developed for battery SOC estimation. These battery models include the kinetic battery model (KiBaM), electrochemical battery model, and electric circuit model. The concept of KiBaM is that not all the energy stored in the battery can be utilized. Based on this concept, the model can capture the relaxation effect and the rated capacity effect. However, it fails to consider the temperature effect. The electrochemical battery model, on the other hand, captures the temperature effect by describing the chemical reactions inside the battery using partial differential equations. The heavy computation requirement, however, makes it difficult to implement for real-time applications.

The electric circuit model can adopt several electric circuit components to describe the terminal voltage dynamics. This electric circuit model can provide the balance between battery modeling fidelity and fast-computational capability, making it attractive for real-time applications. Based on this model, a co-estimation algorithm is disclosed for SOC estimation. By estimating the SOC of the battery using the parameters identified in the same computation cycle, the co-estimation algorithm captures the battery nonlinear dynamic with respect to the SOC and provides an accurate SOC estimation result. The co-estimation algorithm proposed in this disclosure extends its capability to embed the temperature factors by online adaptation of the parameters in real time. Consequently, the parameters adapt their values at the operating temperatures to provide accurate real-time and online SOC estimation. The assumption of the constant temperature condition is relaxed. The electric circuit model is introduced, and the state-space model of the electric circuit model is derived based on the model. The co-estimation algorithm is presented, and the capability to adapt to the temperature effect on the battery's dynamics is explained. Co-estimation algorithm experiments at four different temperature conditions using twelve commercially available lithium-ion batteries are then discussed.

### Electric Circuit Battery Model

A. Electric circuit model

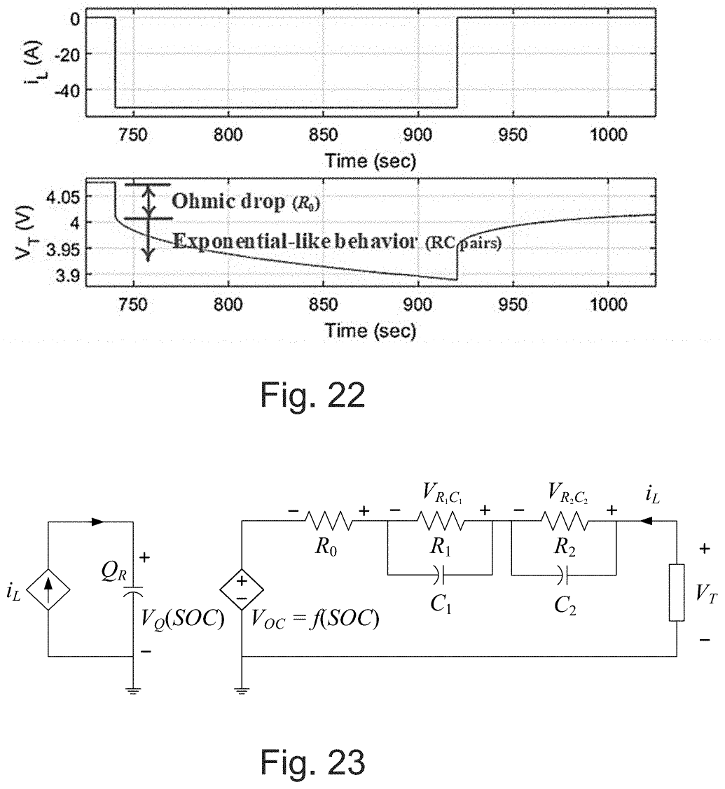

Estimating the SOC of a battery is challenging because of the nonlinear terminal voltage characteristic of a lithium-ion battery. The terminal voltage dynamic is nonlinear due to the Ohmic drop/rise (V_{R}_{₀}), as shown in FIG. 22, which illustrates an example of the terminal voltage dynamic. When the battery experiences a change in the load current, the terminal voltage shows an exponential-like response followed by an Ohmic drop/rise, which may be attributed to the electrochemical reactions inside the battery, including electrolyte resistance, diffusion, and surface reactions.

The nonlinear terminal voltage dynamics can be described using a linear model, called the electric circuit model, which comprises an internal resistance (R₀) and multiple RC pairs (R₁C₁, . . . , Rᵢ, Cᵢ). When the load current changes, the internal resistance causes an abrupt voltage drop/rise, then the RC pairs contribute to the exponential-like voltage dynamics. In this disclosure, the electric circuit model with two RC pairs, as shown in FIG. 23, is used to describe the dynamic of the tested batteries.

B. V_{OC}−SOC profile

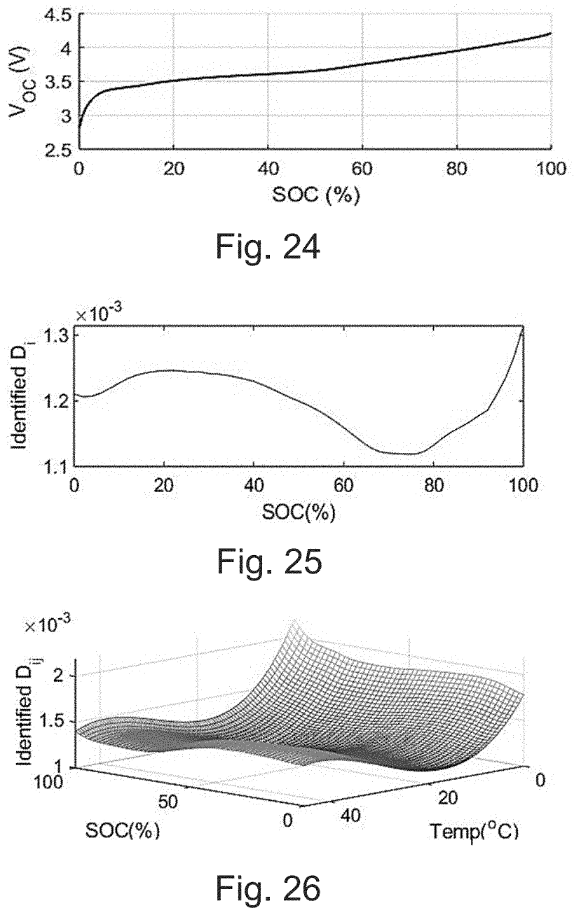

The V_{OC}−SOC profile is another nonlinear characteristic of a lithium-ion battery. FIG. 24 illustrate an example of the V_{OC}−SOC profile of the lithium-ion battery. This profile is determined by the materials used in the anode, cathode, and electrolyte of the battery. This nonlinear relationship can be described as a dependent voltage source in the circuit shown in FIG. 23. The hysteresis effect is not taken into consideration here because the temperature effect is the only factor considered in this discussion. With respect to the temperature conditions, the V_{OC}−SOC profile only changes slightly and is not significant in this estimation process. Therefore, a single V_{OC}−SOC profile can be used for SOC estimation in the developed co-estimation algorithm.

The nonlinear V_{OC}−SOC profile can be described using a set of piecewise linear equations:

$${V}_{o c} ( S O C ) = \{ \begin{matrix}{b}_{1 , 1} S O C + {b}_{0 , 1} , & SO {C}_{0} \leq S O C < S O {C}_{1} \\ {b}_{1 , 2} S O C + {b}_{0 , 2} , & SO {C}_{1} \leq S O C < S O {C}_{2} \\ ⋮ & ⋮ \\ {b}_{1 , i} S O C + {b}_{0 , i} , & {SOC}_{i - 1} \leq S O C < S O {C}_{i}\end{matrix} , \qquad ( 31 )$$

where b_{0,i} and b_{1,i} are the offset and the slope of the piecewise linear equation, and i refers to the specific linear section of the profile.

### C. Battery Dynamics

The battery dynamic (\dot{x}) is a function of battery states (x), input (u), the electric components of the battery electric circuit model (P(SOC,T)), the available capacity of the battery (Q(T)), and the slope of the V_{OC}−SOC profile (b₁(SOC)):

\dot{x}=f(x,u,P(SOC,T),Q(T),b₁(SOC)), (32)

where the battery states (x) include the open-circuit voltage (V_{OC}) and the voltage across the RC pairs (V_{R}_{₁}_{C}_{₁}).

x[V_{OC}V_{R}_{₁}_{C}_{₁}]^{T}. (33)

Each of the electric components is a function of SOC and the temperature of the battery (7):

P(SOC,T)={R₀(SOC,T),R₁(SOC,T),C₁(SOC,T), . . . }, (34)

and b₁(SOC) is the slope of the set of piecewise linear equations describing the nonlinear V_{OC}−SOC profile. The term b₁ is not modeled as a function of temperature because the V_{OC}−SOC profile changes slightly with respect to the temperature and may be considered insignificant in this estimation process. Note that the battery aging effect (SOH) is not discussed in this section.

The parameters of the battery (P(SOC, T), Q(T) and b₁(SOC)) are used to formulate the battery state-space model:

\dot{x}=A(SOC,T)x+B(SOC,T)u, (35)

y=C(SOC,T)x+D(SOC,T)u, (36)

where the state matrices are:

$$\begin{matrix}A ( S O C , T ) = \\ [ \begin{matrix}0 , & 0 , & 0 \\ 0 , & \frac{- 1}{{R}_{1} ( SOC , T ) {C}_{1} ( SOC , T )} & 0 \\ 0 , & 0 , & \frac{- 1}{{R}_{2} ( SOC , T ) {C}_{2} ( SOC , T )}\end{matrix} ] , & ( 37 ) \\ B ( S O C , T ) = {[ \frac{{b}_{1} ( S O C )}{Q ( T )} , \frac{1}{{C}_{1} ( S O C , T )} , \frac{1}{{C}_{2} ( S O C , T )} ]}^{T} , & ( 38 ) \\ C ( SOC , T ) = [ 1 , 1 , 1 ] , and & ( 39 ) \\ D ( S O C , T ) = {R}_{0} ( SOC , T ) , ∀ {SOC}_{i} < SOC < S O {C}_{i + 1} and {T}_{j} < T < {T}_{j + 1} . & ( 40 )\end{matrix}$$

The state-space model can then be derived into a continuous-time transfer function, as written in Equation (41).

$$\frac{{V}_{T} ( s )}{{I}_{L} ( s )} = {R}_{0} ( SOC , T ) + \frac{1 / {C}_{1} ( SOC , T )}{s + 1 / {R}_{1} ( SOC , T ) {C}_{1} ( SOC , T )} + \frac{1 / {C}_{2} ( SOC , T )}{s + 1 / {R}_{2} ( SOC , T ) {C}_{2} ( SOC , T )} + \frac{{b}_{1} ( SOC ) / Q ( T )}{s} . \qquad ( 41 )$$

### Co-Estimation of SOC

### A. Co Estimation Considering the SOC Dynamic

The co-estimation algorithm has been considered at a constant temperature condition, e.g., 25° C. (room temperature). The state matrices defined in co-estimation algorithms (Aᵢ, Cᵢ, Dᵢ in Equations (42) and (43)) are generally modeled only as functions of the SOC of the battery. For simplicity, the SOC-related variables include a subscript with an index i to refer to the specific linear section of the V_{OC}−SOC profile.

\dot{x}=Aᵢx+Bᵢu, (42)

y=Cᵢx+Dᵢu, (43)

where the Aᵢ, Bᵢ, Cᵢ, and Dᵢ matrices are:

$$\begin{matrix}{A}_{i} = A ( SOC , 25 ° C ) = \\ [ \begin{matrix}0 & 0 & 0 \\ 0 & - 1 / {R}_{1 , i} {C}_{1 , i} & 0 \\ 0 & 0 & - 1 / {R}_{2 , i} {C}_{2 , i}\end{matrix} ] , & ( 44 ) \\ {B}_{i} = B ( SOC , 25 ° C ) = {[ {b}_{1 , i} / Q 1 / {C}_{1 , i} 1 / {C}_{2 , i} ]}^{T} , & ( 45 ) \\ {C}_{i} = C ( SOC , 25 ° C ) = \begin{matrix}[ 1 & 1 & 1 ]\end{matrix} , and & ( 46 ) \\ {D}_{i} = D ( SOC , 25 ° C ) = {R}_{0 , i} , ∀ S O {C}_{i} < S O C < S O {C}_{i + 1} . & ( 47 )\end{matrix}$$

The available capacity of the battery remains constant in the constant temperature condition. Note that the battery aging effect (SOH) is not discussed here.

Q=Q(25° C.). (48)

The state-space model is derived into a continuous-time transfer function, as written in Equation (49).

$$\frac{{V}_{T} ( s )}{{I}_{L} ( s )} = {R}_{0 , i} + \frac{1 / {C}_{1 , i}}{s + 1 / {R}_{1 , i} {C}_{1 , i}} + \frac{1 / {C}_{2 , i}}{s + 1 / {R}_{2 , i} {C}_{2 , i}} + \frac{{b}_{1 , i} / Q ( 25 ° C )}{s} . \qquad ( 49 )$$

As an illustration, FIG. 25 shows the identified Di state matrix as a function of SOC.

### B. Co Estimation Considering Both the SOC Dynamic and the Temperature Dynamic

The co-estimation algorithm proposed in this disclosure extends its capability to embed the temperature by online adapting of the parameters in real-time. Consequently, the parameters adapt their values at the operating temperature to provide accurate real-time SOC estimation. The assumption of the constant temperature condition is thus relaxed. The state-space model can be formulated in Equations (50) and (51).

\dot{x}=Aᵢⱼx+Bᵢⱼu, (50)

y=Cᵢⱼx+Dᵢⱼu, (51)

The state matrices (Aᵢⱼ, Rᵢⱼ, Cᵢⱼ, and Dᵢⱼ) can be formulated as a set of piece-wise linear matrices with respect to both the battery's SOC and temperature:

$$\begin{matrix} {A}_{ij} = A ( S O C , T ) = [ \begin{matrix}0 & 0 & 0 \\ 0 & - 1 / {R}_{1 , ij} , {C}_{1 , ij} & 0 \\ 0 & 0 & - 1 / {R}_{2 , ij} {C}_{2 , ij}\end{matrix} ] , & ( 52 ) \\ {B}_{ij} = B ( S O C , T ) = {[ {b}_{1 , i} / {Q}_{j} 1 / {C}_{1 , ij} 1 / {C}_{2 , ij} ]}^{T} , & ( 53 ) \\ {C}_{ij} = C ( S OC , T ) = \begin{matrix}[ 1 & 1 & 1 ]\end{matrix} , and & ( 54 ) \\ {D}_{ij} = D ( S O C , T ) = {R}_{0 , ij} , ∀ {SOC}_{i} < SOC < SO {C}_{i + 1} and {T}_{j} < T < {T}_{j + 1} . & ( 55 )\end{matrix}$$

where i represents the i^{th} linear region of the V_{OC}−SOC profile, i=1, . . . , m, and j denotes the temperature condition, j=1, . . . , n.

To adapt to the temperature, two approaches can be adopted. First, the online parameter identification in real-time approaches can be used to identify the temperature-dependent parameters. Second, the available capacity, which is a function of temperature, can be embedded in the co-estimation algorithm at the b^{1,i}/Qⱼ factor, making the disclosed co-estimation algorithm independent of the need for the available capacity of the battery. The continuous-time transfer function can be written in Equation (56).

$$\frac{{V}_{T} ( s )}{{I}_{L} ( s )} = {R}_{0 , i j} + \frac{1 / {C}_{1 , ij}}{s + 1 / {R}_{1 , ij} {C}_{1 , ij}} + \frac{1 / {C}_{2 , ij}}{s + 1 / {R}_{2 , ij} {C}_{2 , ij}} + \frac{{b}_{1 , i} / {Q}_{j}}{s} . \qquad ( 56 )$$

The adapted R_{0,ij}, R_{1,ij}, C_{1,ij}, R_{2,ij}, b_{1,i} and Qⱼ values, therefore embed the temperature effect by using the current online measurement at the current operating temperature. As an illustration, FIG. 26 shows an example of an identified Dᵢⱼ matrix as a function of the SOC and temperature of the battery. In summary, the co-estimation algorithm is developed for online SOC estimation. In real-time operation, the algorithm continuously updates its parameter values when the temperature and the SOC are changing.

### C. Parameter Identification

To identify the parameters of the battery, the continuous-time transfer function, as written in Equation (56), can first be transformed into a discrete-time transfer function since the load current and terminal voltage data are acquired in the discrete-time domain with a fixed sampling time. The continuous-time domain can be converted to the discrete-time domain using the bilinear transform

$$( s \to \frac{2}{T} \frac{z - 1}{z + 1} ) .$$

The sampling time (T) is set as one second in this disclosure.

The linear regression analysis is adopted to identify the parameters of the electric circuit model. To perform the linear regression analysis, the system can be written in an autoregressive-moving-average model form (ARMA):

V_{T}(k)+a₁V_{T}(k−1)+ . . . +aₙV_{T}(k−n)=c₀I_{L}(k)+c₁I_{L}(k−1)+ . . . +cₘI_{L}(k−m). (57)

where k is the timestamp, and an and cm are the coefficients of the discrete-time transfer function, which is converted from Equation (56) using a bilinear transform. The discrete-time transfer function should be converted back to the continuous-time domain, as written in Equation (56), to acquire the parameters of the electric circuit model.

### D. Luenberger Observer

The SOC Luenberger observer can be designed based on the battery state-space model. The input (u) of the observer is the load current (I_{L}) and the output (y) is the terminal voltage (V_{T}):

\hat{x}=Aᵢⱼ\hat{x}+Bᵢⱼu+L(y−ŷ), (58)=

ŷ=Cᵢⱼ\hat{x}+Dᵢⱼu, (59)

where the system realization (Aᵢⱼ, Bᵢⱼ, Cᵢⱼ, Dᵢⱼ) are defined in Equations (52) to (55).

The observer gain (L) determines the convergence speed of the observer. If the observer gain is set high, the observer states are estimated faster, but the observer is sensitive to measurement noise. In this disclosure, the pole-placement approach is used to determine a suitable observer gain by assigning suitable estimator poles (eigenvalues) of the (Aᵢⱼ−LCᵢⱼ) matrix:

e=x−\hat{x}=(Aᵢⱼ−LCᵢⱼ)e, (60)

where e is the error between the observed states and the states of the real battery system.

As stated in Equation (52), the Aᵢⱼ matrix is a diagonal matrix and has its poles along the diagonal. So, the new poles are assigned as P^{T}=[p₁, p₂, p₃], with:

$$\begin{matrix}{p}_{2} = {p}_{{\hat{V}}_{{R}_{1} {C}_{1}}} = G \times {A}_{ij} ( 2 , 2 ) = G \times ( - 1 / {R}_{1 , ij} {C}_{1 , ij} ) , & ( 61 ) \\ {p}_{3} = {p}_{{\hat{V}}_{{R}_{2} {C}_{2}}} = G \times {A}_{ij} ( 3 , 3 ) = G \times ( - 1 / {R}_{2 , ij} {C}_{2 , ij} ) , & ( 62 )\end{matrix}$$

where G is the gain for the pole. For example, the poles of the matrix (Aᵢⱼ−LCᵢⱼ) can be set to be three times faster than the poles of the battery system. However, p₁ should be assigned manually because the pole of the V_{OC} state in the battery system is zero. In the following results, p₁ was set as 0.5.

### Experimental Results

### A. Battery Charging/Discharging Experiment Setup

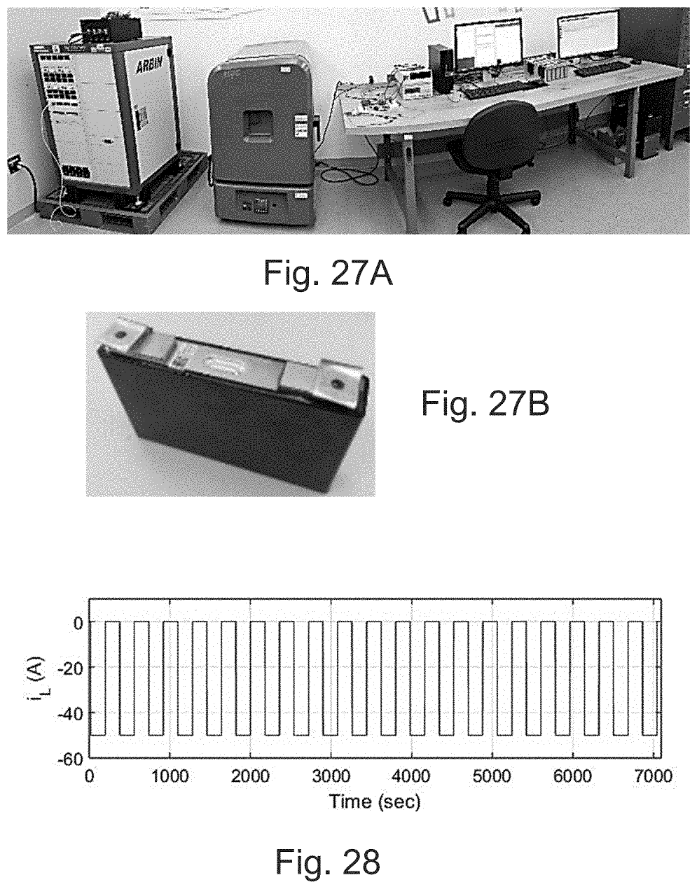

To evaluate the performance of the proposed co-estimation algorithm at different temperatures, a series of experiments were conducted. The battery hardware-in-the-loop (HIL) testbed in the ADAC lab (Advanced Diagnosis, Automation, and Control Laboratory) that was used for the evaluation is shown in FIG. 27A.

Twelve 50 Ah lithium-ion batteries were tested, with an example shown in FIG. 27B. At least two battery cells were tested at each temperature for statistical significance. These batteries were tested in a new condition, so the aging effect was not considered in the experiments. Table II lists the temperatures and the number of batteries tested at those temperatures.

TABLE II
Temperatures and the number of the battery tested

| Temperature (° C.) | Number |
|---|---|
| 45 | 4 |
| 25 | 4 |
| 10 | 2 |
| 0 | 2 |

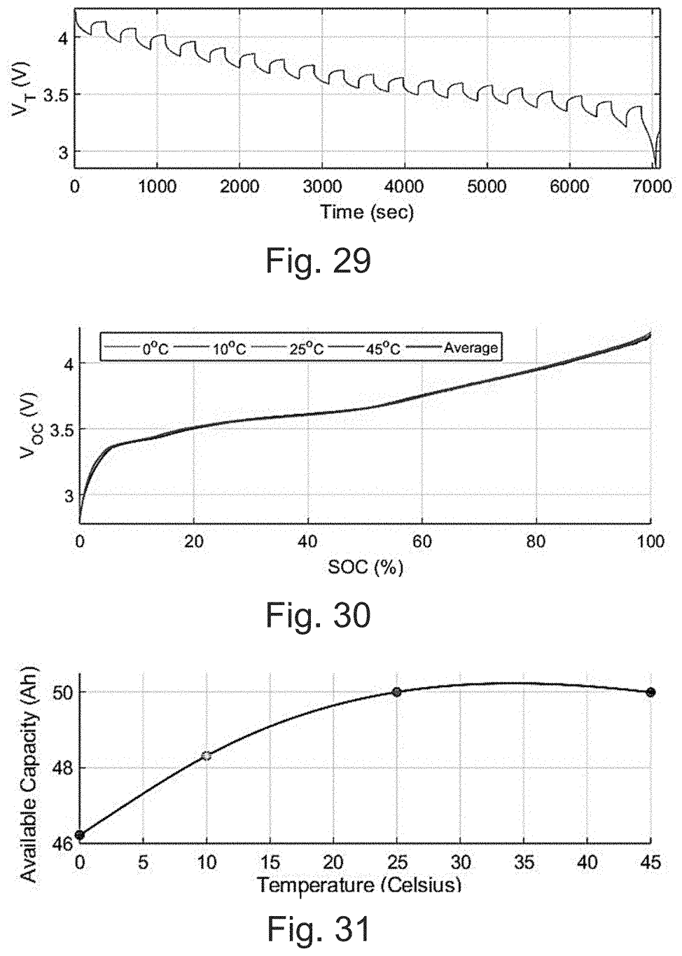

Before the discharging experiments were initiated, the batteries were charged to full using a CCCV profile at room temperature (25° C.). After the batteries were fully charged, they were discharged using the same pre-defined pulse discharging profile at different temperature conditions, as shown in FIG. 28. The profile was a loop of three minutes of discharging at the 1C-rate (50 A) and three minutes of resting. The experiment was terminated once the terminal voltage of the battery reached the cutoff voltage (2.8V), as shown in FIG. 29.

B. V_{OC}−SOC profile

To acquire the V_{OC}−SOC profile without taking the hysteresis effect into consideration, the battery was discharged at the C/25-rate (2 A). At this low C-rate, the measured voltage can be considered the open-circuit voltage. The same C-rate discharging experiment was repeated at different temperatures (0° C., 10° C., 25° C., 45° C.) to obtain the V_{OC}−SOC profiles. The V_{OC}−SOC profiles are similar at the different temperatures, as shown in FIG. 30. For the purpose of simplicity, one representative V_{OC}−SOC profile was obtained by averaging the V_{OC}−SOC profiles acquired at the different temperatures, as shown in FIG. 30.

C. Capacity Profile with Respect to Temperature

Comparing the V_{OC}−SOC profile, the available capacity of the battery is highly dependent on the temperature, as shown in FIG. 31. The available capacity was measured when the batteries were operated using the pulse discharging profile, but it is not an input of the proposed co-estimation algorithm because the available capacity of the battery (Qⱼ) is embedded in the algorithm. The dots shown in FIG. 31 represent the available capacities of the battery cells examined at defined temperatures (0° C., 10° C., 25° C., 45° C.). The plotted line illustrates the general profile of available capacity versus temperature. The result shows that the tested battery has approximately the maximum available capacity when at about 35° C. The capacity reduces when the temperature is higher or lower than room temperature.

D. Coulomb Counting Result with Respect to Temperature

As previously discussed, Coulomb counting is a SOC estimation algorithm. It can also be used as an offline reference to examine the accuracy of newly proposed algorithms. This algorithm is accurate if the available capacity of the battery is determined accurately. The accumulated sensing error may be ignored in this analysis because the current sensor in the battery tester is calibrated to ±5 mA.

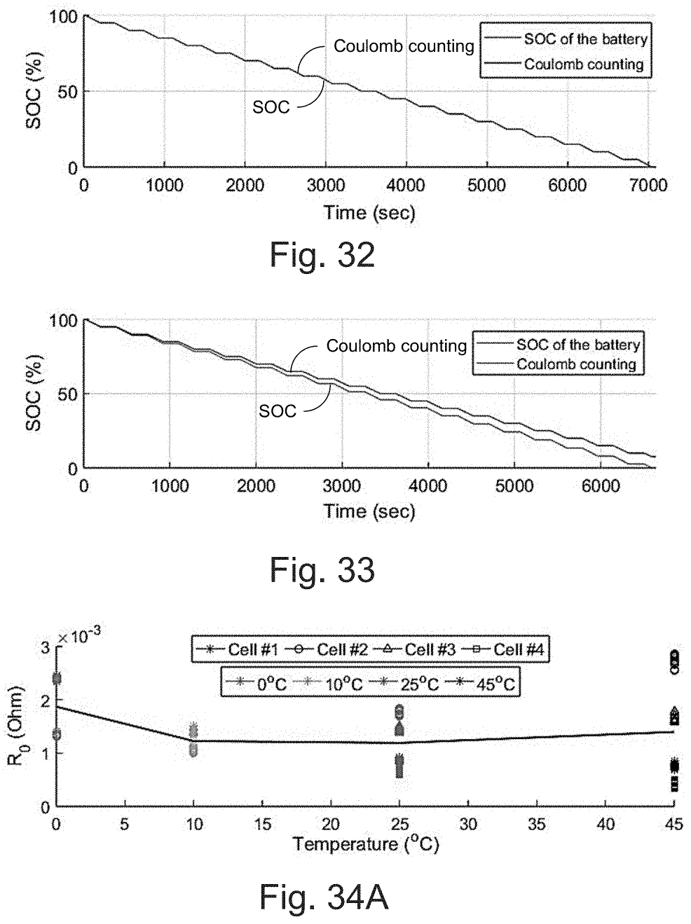

The Coulomb counting algorithm provides accurate SOC estimation at room temperature (25° C.), as shown in FIG. 32. The estimation error is less than 0.05%. It is because the available capacity at room temperature is almost the same as the rated capacity. However, when the temperature moves away from the room temperature, the available capacity is different from the rated capacity, resulting in the increase in the SOC estimation error. For example, the SOC estimation error is accumulated at 0° C., as shown in FIG. 33, assuming zero initial SOC estimation error. Under these conditions, the estimation error is 6.8% at the end of the estimation.

E. Co-Estimation Algorithm Result with Respect to Temperature

Identified Parameters with Respect to Temperature:

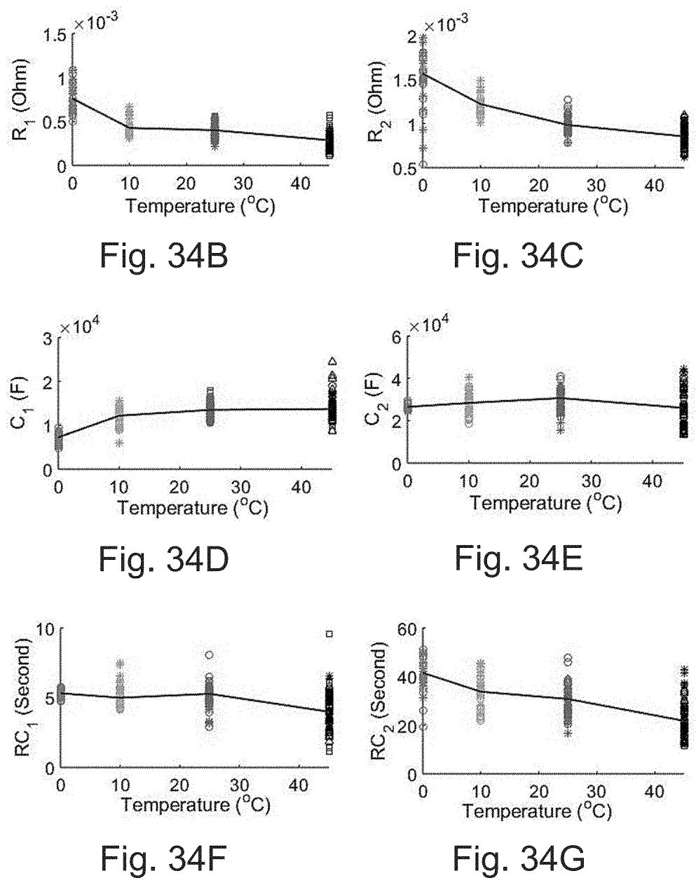

The regional-awareness parameter identification algorithm is adopted in the co-estimation algorithm to acquire accurate parameters. The result shows that the identified parameters are functions of temperature, as shown in FIGS. 34A-34G. Note that the markers in the plots (star, circle, triangle, and square) represent the index of the cells in the experiment at certain temperature conditions. The temperature condition of the experiments can be seen by the plotted measurements.

The plotted line in FIGS. 34A-34G represents the general profile of the averaged value with respect to temperature. The resistances of the RC pairs (R₁ and R₂) gradually reduce as the temperature increases, as shown in FIGS. 34B and 34C. The capacitances of the RC pairs (C₁ and C₂) have opposite profiles to the profile of R₁ and R₂, as shown in FIGS. 34D and 34E. FIGS. 34F and 34G show the time constants of the two RC pairs. The relationship of the internal resistance (R₀) to temperature, however, cannot be concluded because it is highly affected by the cell-to-cell difference, as shown in FIG. 34A.

Identified Parameters with Respect to SOC:

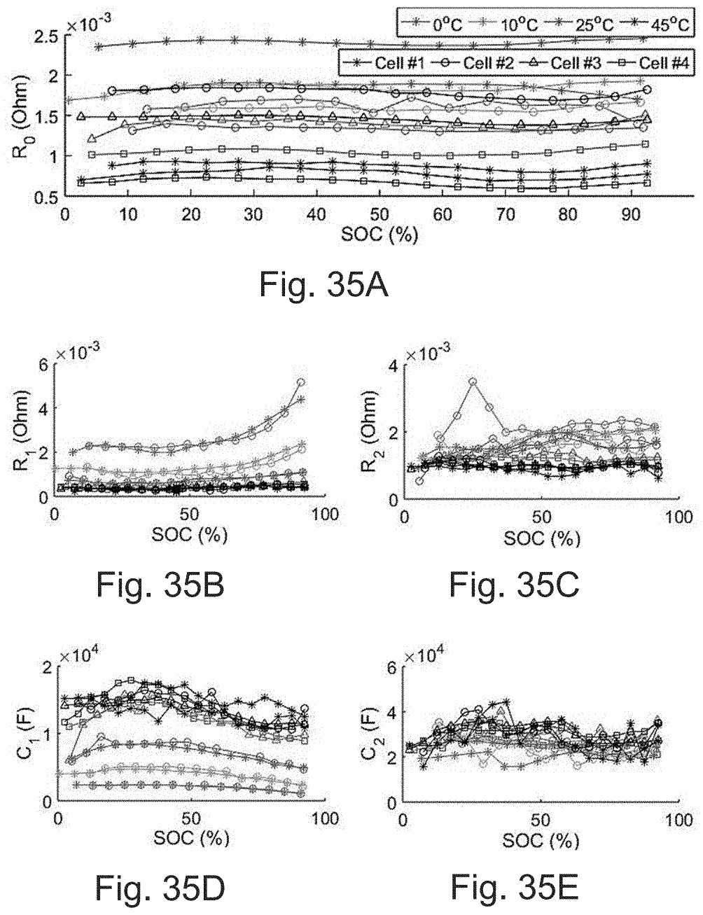

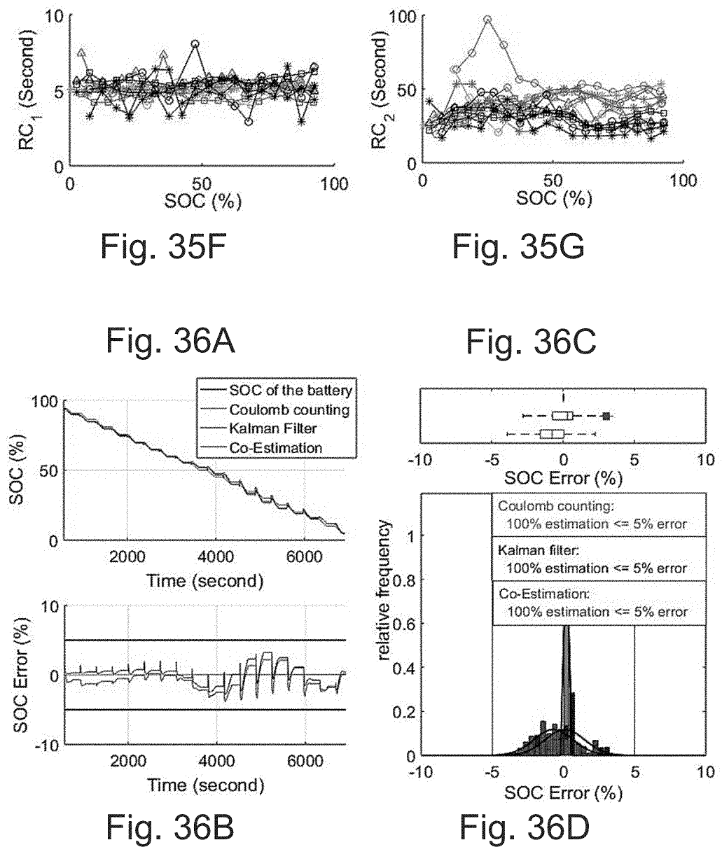

The identified parameters are also functions of SOC, as shown in FIGS. 35A-35G. The SOC is a fundamental factor that can always be taken into consideration. The SOC estimation should meet the industrial requirement (5% SOC estimation error) when the battery is operated from full capacity to empty, during which the battery dynamics change. Therefore, the co-estimation algorithm exhibits the ability to adapt to dynamic change caused by the change in SOC. As in FIGS. 34A-34G, the markers represent the cells operated at each temperature condition.

The resistances of the RC pairs (R₁ and R₂) are larger at two ends, but smaller when the SOC is about 50%, as shown in FIGS. 35B and 35C. The capacitances of the RC pairs (C₁ and C₂) show the opposite profiles, as shown in FIGS. 35D and 35E. The combined effect results in the flat RC time constants (R₁C₁ and R₂C₂) profiles among all the SOC rage, as shown in FIGS. 35F and 35G. The internal resistance (R₀) also shows an obvious cell-to-cell difference and therefore conclusions cannot be drawn about the relationship with SOC, as shown in FIG. 35A.

SOC Estimation Result Comparison:

FIGS. 36A-38D show examples of the SOC estimation results using the proposed co-estimation algorithm at different temperatures. The results are compared with the Coulomb counting approach (using the rated capacity of the battery) and the Kalman filter approach. These results are showcases of the cell at the assigned temperature. Note that the initial states of the co-estimation algorithm and the Kalman filter approach are zero, and the initial condition of the Coulomb counting approach is the same as the battery SOC at the beginning of the estimation to achieve zero initial SOC error.

FIGS. 36A-36D illustrate examples of (a) the SOC estimation result, (b) the SOC estimation error, (c) boxplot and (d) histogram plots of the SOC error (for cell #4) at 25° C. At room temperature, the SOC estimation of all algorithms is accurate, as shown in FIGS. 36A and 36B. The SOC of the battery is plotted in FIG. 36A, which is the item to examine for the performances of the algorithms. It was estimated using the Coulomb counting approach and employing the correct capacity of the battery, where the correct available capacity of the battery was estimated after the battery was discharged from full to empty using the pulse discharging profile, as shown in FIGS. 28 and 29. The horizontal lines in FIG. 36B represent the 5% SOC estimation error, which is recognized as the industrial satisfaction criteria.

The SOC estimations of the Kalman filter approach and the proposed co-estimation algorithm fluctuate when the SOC is low because the V_{OC}−SOC profile is relatively steep in that SOC range. After mapping the estimated V_{OC} to SOC using the V_{OC}−SOC profile with a steep slope, a small error will be scaled up to a large estimation error. The standard deviation of the co-estimation algorithm is 1.36% at room temperature, and 100% of the SOC estimation falls within the 5% estimation error range, as shown in FIG. 36D. Compared to the Kalman filter approach and the co-estimation algorithm, the Coulomb counting approach provides the best estimation at room temperature.

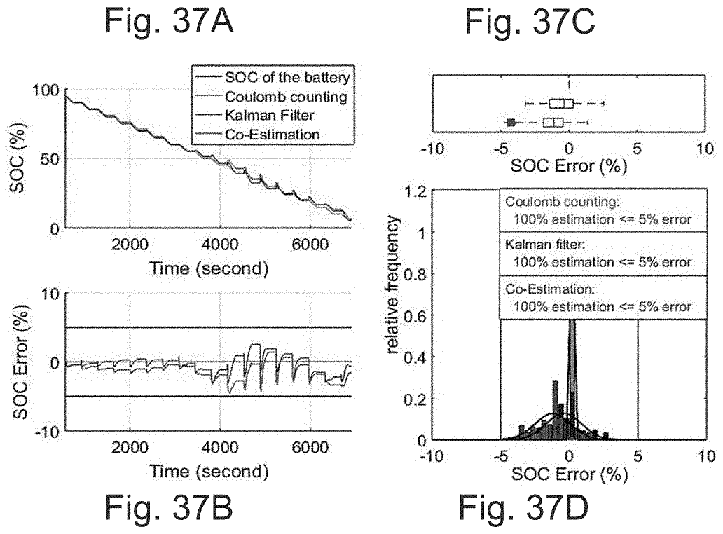

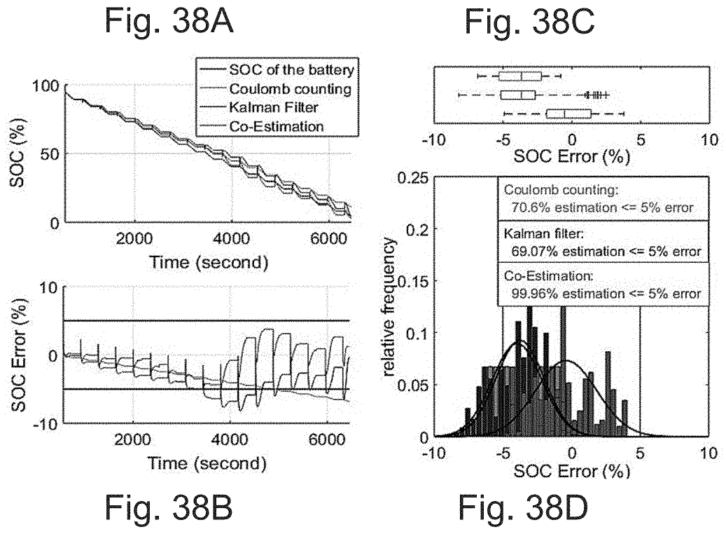

FIGS. 37A-37D illustrate examples of (a) the SOC estimation result, (b) the SOC estimation error, (c) boxplot and (d) histogram plots of the SOC error (for cell #4) at 45° C. The estimation results at 45° C. are similar because the available capacity of the battery at this temperature is almost the same as the available capacity at 25° C., as shown in FIG. 31. However, when the temperature changes from 25° C. to 0° C., the available capacity drops from 50 Ah to 46.2 Ah, which is 92.4% of the rated capacity. FIGS. 37A-37D illustrate examples of (a) the SOC estimation result, (b) the SOC estimation error, (c) boxplot and (d) histogram plots of the SOC error (for cell #1) at 0° C. Without the correct available capacity, the Coulomb counting approach no longer provides accurate SOC estimation, as shown in FIGS. 38A-38D. The Kalman filter approach also provides poor SOC estimation at 0° C. because of the failure to capture the temperature effect. Compared to the Coulomb counting approach and the Kalman filter approach, the proposed co-estimation algorithm still provides a similar SOC estimation result among different temperature conditions because of its consideration of the temperature effect. Table III summarizes the average performance of the algorithms at different temperatures.

TABLE III
Average Performance Comparisons

| Temperature | | SOC estimation error (%) | | | |
|---|---|---|---|---|---|
| (° C.) | Algorithm | \|Max\| | Mean | Median | s.t.d. |
| 45 | Coulomb | 0.0331 | 0.0182 | 0.0180 | 0.0084 |
| | counting | | | | |
| | Kalman filter | 3.5496 | −0.0136 | −0.0940 | 1.2828 |
| | Co-Estimation | 5.0635 | −1.5576 | −1.2496 | 1.2007 |
| 25 | Coulomb | 0.0490 | 0.0271 | 0.0270 | 0.0126 |
| | counting | | | | |
| | Kalman filter | 3.9708 | 0.5598 | 0.6790 | 1.4798 |
| | Co-Estimation | 4.0106 | −0.7232 | −0.6405 | 1.3593 |
| 10 | Coulomb | 3.0220 | −1.6572 | −1.6842 | 0.7831 |
| | counting | | | | |
| | Kalman filter | 5.2715 | −1.0823 | −0.9139 | 1.4949 |
| | Co-Estimation | 4.059 | 0.0192 | −0.1058 | 1.4969 |
| 0 | Coulomb | 6.8077 | −3.7325 | −3.6544 | 1.7442 |
| | counting | | | | |
| | Kalman filter | 8.5996 | −4.0858 | −3.8126 | 1.8640 |
| | Co-Estimation | 4.8243 | −0.5709 | −0.8615 | 1.9786 |

This disclosure has presented a co-estimation algorithm to estimate the SOC of a battery accurately at different temperatures. While the SOC algorithm has focused on constant temperature conditions, this can reduce its utility for real-time applications. The algorithm presented in this disclosure extends its capability to embed the temperature factors by online adapting of the parameters in real time. Consequently, the parameters adapt their values to the temperature, thereby providing accurate real-time SOC estimation. Also, the proposed co-estimation algorithm is developed as an available capacity-independent algorithm, making the proposed algorithm suitable for real-world applications.

The performance of the proposed co-estimation algorithm was examined using twelve commercialized batteries at various temperatures (from 0° C. to 45° C.). The performance of the proposed co-estimation algorithm was compared with two prevailing SOC estimation algorithms: the Coulomb counting approach and the Kalman filter approach. Even though both algorithms show satisfactory performance at room temperature, the Coulomb counting and Kalman filter approaches result are poor at 10° C. and 0° C. because they fail to adapt to the temperature. The proposed co-estimation algorithm performs better than these prominent algorithms because it successfully adapts to the temperature, thus providing the SOC estimation at various temperature accurately.

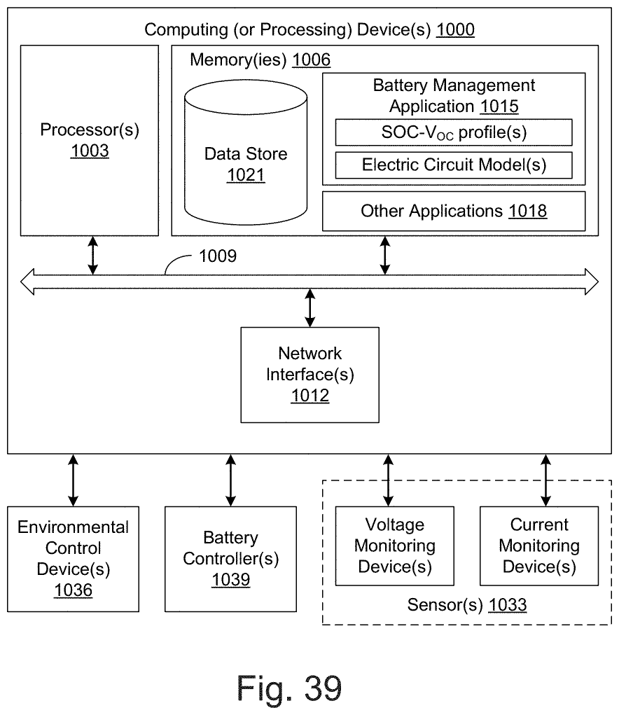

FIG. 39 shows a schematic block diagram illustrating an example of a computing (or processing) device 1000. In some embodiments, among others, the computing (or processing) device 1000 may comprise one or more computing/processing device such as, e.g., a smartphone, tablet, computer, etc. The computing (or processing) device 1000 includes processing circuitry comprising at least one processor circuit, for example, having a processor 1003 and a memory 1006, both of which are coupled to a local interface 1009. To this end, each computing (or processing) device 1000 may comprise, for example, at least one server computer or like device, which can be utilized in a cloud based environment. The local interface 1009 may comprise, for example, a data bus with an accompanying address/control bus or other bus structure as can be appreciated.

In some embodiments, the computing (or processing) device 1000 can include one or more network interfaces 1012. The network interface 1012 may comprise, for example, a wireless transmitter, a wireless transceiver, and/or a wireless receiver. The network interface 1012 can communicate to a remote computing/processing device or other components using a Bluetooth, WiFi, or other appropriate wireless protocol. As one skilled in the art can appreciate, other wireless protocols may be used in the various embodiments of the present disclosure. The network interface 1012 can also be configured for communications through wired connections.

Stored in the memory 1006 are both data and several components that are executable by the processor(s) 1003. In particular, stored in the memory 1006 and executable by the processor 1003 can be a battery management application 1015, and potentially other applications 1018. In this respect, the term “executable” means a program file that is in a form that can ultimately be run by the processor(s) 1003. Also stored in the memory 1006 may be a data store 1021 and other data. In addition, an operating system may be stored in the memory 136 and executable by the processor(s) 1003. It is understood that there may be other applications that are stored in the memory 1006 and are executable by the processor(s) 1003 as can be appreciated.

Examples of executable programs may be, for example, a compiled program that can be translated into machine code in a format that can be loaded into a random access portion of the memory 1006 and run by the processor(s) 1003, source code that may be expressed in proper format such as object code that is capable of being loaded into a random access portion of the memory 1006 and executed by the processor(s) 1003, or source code that may be interpreted by another executable program to generate instructions in a random access portion of the memory 1006 to be executed by the processor(s) 1003, etc. Where any component discussed herein is implemented in the form of software, any one of a number of programming languages may be employed such as, for example, C, C++, C#, Objective C, Java®, JavaScript®, Perl, PHP, Visual Basic®, Python®, Ruby, Flash®, or other programming languages.

The memory 1006 is defined herein as including both volatile and nonvolatile memory and data storage components. Volatile components are those that do not retain data values upon loss of power. Nonvolatile components are those that retain data upon a loss of power. Thus, the memory 1006 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 1003 may represent multiple processors 1003 and/or multiple processor cores, and the memory 1006 may represent multiple memories 1006 that operate in parallel processing circuits, respectively. In such a case, the local interface 1009 may be an appropriate network that facilitates communication between any two of the multiple processors 1003, between any processor 1003 and any of the memories 1006, or between any two of the memories 1006, etc. The local interface 1009 may comprise additional systems designed to coordinate this communication, including, for example, performing load balancing. The processor 1003 may be of electrical or of some other available construction.

Although the battery management application 1015, and other various applications 1018 described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

Also, any logic or application described herein, including the battery management application 1015, that comprises software or code can be embodied in any non-transitory computer-readable medium for use by or in connection with an instruction execution system such as, for example, a processor 1003 in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

Further, any logic or application described herein, including the battery management application 1015, may be implemented and structured in a variety of ways. For example, one or more applications described may be implemented as modules or components of a single application. For example, the battery management application 1015 can include a wide range of modules such as, e.g., an electric circuit model, V_{OC}−SOC profile(s), or other modules that can provide specific functionality and control to the monitored battery and its environment. Further, one or more applications described herein may be executed in shared or separate computing/processing devices or a combination thereof. For example, a plurality of the applications described herein may execute in the same computing (or processing) device 1000, or in multiple computing/processing devices in the same computing environment. To this end, each computing (or processing) device 1000 may comprise, for example, at least one server computer or like device, which can be utilized in a cloud based environment.

The battery management application 1015 will now be discussed with respect to simulation of estimation of the state of charge (SOC) of a battery. As previously discussed, the battery management application can utilize a model of the battery, V_{OC}−SOC profiles or other information to estimate a condition of the battery. Sensors 1033 such as, e.g., voltage and current monitoring device(s) can be used to monitor the condition of the battery and provide information that can be used by the battery management application 1015 to determine the SOC of the battery. The estimations can be used to provide control signals to, e.g., environmental control device(s) 1036 and/or battery controller(s) 1039. The battery management application 1015 can provide the controls signals directly or can provide indications of the battery condition to another application or device (e.g., an environmental control device 1036 or battery controller 1039) that can control the battery or its environment using the provided battery condition information. The environmental control device(s) 1036 can adjust the environment of the battery to improve operational capabilities. For example, the battery management application 1015 can provide control signals to the environmental control device(s) 1036 to adjust temperature to improve or maximize the capabilities of the battery based on the SOC estimation. The battery controller(s) 1039 can control charging and/or discharging of the battery to improve or maximize the characteristics of the battery based on the SOC estimation. For example, the sequence of discharge and rest can be controlled to allow for energy to be extracted over an extended period of time. Charging rates of the battery can also be controlled to ensure that the appropriate charge levels can be achieved.

The present disclosure is related to systems, methods, and/or computer program products for state of charge (SOC) estimation. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as languages for smartphones, Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A system, comprising:
a battery;
one or more sensors that monitor conditions of the battery, the conditions comprising terminal voltage and terminal current of the battery;
processing circuitry comprising a processor and memory; and
a battery management application that, when executed by the processing circuitry, causes the processing circuitry to:
determine, using iterative estimation, one or more parameters of a battery model of the battery;
determine, using the iterative estimation, a relationship between the one or more parameters of the battery model, the terminal current of the battery, and the terminal voltage of the battery;
determine one or more states of the battery based at least in part upon the one or more parameters of the battery model, the terminal current of the battery, and the terminal voltage of the battery using an observer function defined by:
$$\dot{SOC} = \frac{1}{{Q}_{R}} {I}_{L} + L ( f ( S O C ) - {V}_{OC} ) ,$$
where Q_{R} is a nominal capacity of the battery, i_{L} is the terminal current of the battery, L is a gain of the observer determined by the one or more parameters of the battery model, and f(SOC) defines a relationship between a battery open circuit voltage (V_{OC}) and a state of charge (SOC) of the battery; and
generate a control signal to adjust operation of the battery or an environment of the battery based at least in part upon the one or more states of the battery.

2. The system of claim 1, wherein the one or more states comprise the SOC of the battery or a state of health (SOH) of the battery.

3. The system of claim 1, wherein the one or more parameters comprise an internal resistance, a resistance for a small resistor, a capacitance, a slope of a piecewise linear approximation of a V_{OC}−SOC (voltage open circuit−state of charge) curve, and a slope intercept of the piecewise linear approximation of the V_{OC}−SOC curve.

4. The system of claim 1, wherein the battery comprises a lithium-polymer battery.

5. The system of claim 1, wherein the battery management application causes the processing circuitry to estimate an actual capacity of the battery utilizing the one or more states and the one or more parameters.

6. The system of claim 1, wherein the battery management application causes the processing circuitry to identify the one or more parameters of the battery by selecting one or more input-output samples of the iterative estimation during operation of the battery.

7. The system of claim 1, wherein the iterative estimation utilizes moving window least-squares (LS) parameter identification.

8. The system of claim 1, wherein the f(SOC) comprises a look-up table including experimental data, a cubic spline function, or a linear function defining the relationship between V_{OC} and SOC of the battery.

9. The system of claim 1, wherein a real-time analysis of the one or more states occurs while the battery is in operation within an electrical device.

10. The system of claim 9, wherein the electrical device comprises a plug-in hybrid electric vehicle (PHEV), a plug-in electric vehicle (PEV), or a smart grid system.

11. A system, comprising:
a battery;
one or more sensors that monitor conditions of the battery, the conditions comprising terminal voltage, terminal current and current operating temperature of the battery;
processing circuitry comprising a processor and memory; and
a battery management application that, when executed by the processing circuitry, causes the processing circuitry to:
determine one or more current parameters of an electric circuit model of the battery based at least in part upon the current operating temperature;
determine an available capacity of the battery based at least in part upon the current operating temperature;
determine one or more states of the battery based at least in part upon the one or more current parameters of the electric circuit model of the battery, the available capacity of the battery, and a slope of an open circuit voltage−state of charge (V_{OC}−SOC) profile of the battery using an observer function; and
generate a control signal to adjust operation of the battery or an environment of the battery based at least in part upon the one or more states of the battery.

12. The system of claim 11, wherein the observer function is a SOC Luenberger observer function.

13. The system of claim 11, wherein the one or more current parameters are determined using linear regression analysis.

14. The system of claim 13, wherein the linear regression utilizes an autoregressive-moving-average model.

15. The system of claim 11, the V_{OC}−SOC profile is a nonlinear profile defined by a set of piecewise linear equations.

16. The system of claim 11, wherein the electric circuit model of the battery comprises an internal resistance (R₀) and multiple resistor-capacitor pairs (R₁C₁, . . . , Rᵢ, Cᵢ).

17. The system of claim 11, wherein the one or more states comprise a current SOC of the battery.

18. The system of claim 11, wherein the battery management application causes the processing circuitry to estimate an actual capacity of the battery utilizing the one or more states and the one or more parameters.

19. The system of claim 11, wherein a real-time analysis of the one or more states occurs while the battery is in operation within an electrical device.

20. The system of claim 19, wherein the electrical device comprises a plug-in hybrid electric vehicle (PHEV), a plug-in electric vehicle (PEV), or a smart grid system.
